(19) United States
(12) Patent Application Publication
(10) Pub. No.: US 2025/0226851 A1
(43) Pub. Date: Jul. 10, 2025

(54) ENCODING METHOD, DECODING METHOD, ENCODING APPARATUS, DECODING APPARATUS, ELECTRONIC DEVICE, AND STORAGE MEDIUM

(71) Applicant: Douyin Vision Co., Ltd., Beijing (CN)

(72) Inventors: Dejun ZHANG, Beijing (CN); Ziqian Wu, Beijing (CN); Jiawei Jiang, Beijing (CN); He Wang, Beijing (CN); Kunpeng Lin, Beijing (CN)

(21) Appl. No.: 19/094,711

(22) Filed: Mar. 28, 2025

Related U.S. Application Data
(63) Continuation of application No. PCT/CN2023/122452, filed on Sep. 28, 2023.

(30) Foreign Application Priority Data
Sep. 29, 2022 (CN) 202211204121.9

(51) Int. Cl. H04B 1/66; H03M 7/30

(52) U.S. Cl. CPC H04B 1/66; H03M 7/6005; H03M 7/6011

(57) ABSTRACT

An encoding method, a decoding method, an encoding apparatus, a decoding apparatus, an electronic device, and a storage medium. The encoding method includes: obtaining at least two multiple description signals according to a to-be-coded signal, the at least two multiple description signals including a first multiple description signal and a second multiple description signal; performing first quantization on the first multiple description signal to obtain a first candidate quantized signal set, and performing second quantization on the second multiple description signal to obtain a second candidate quantized signal set; obtaining a first quantized signal corresponding to the first multiple description signal and a second quantized signal corresponding to the second multiple description signal according to the first candidate quantized signal set and the second candidate quantized signal set; and encoding the first quantized signal and the second quantized signal to generate a target bitstream corresponding to the to-be-coded signal.

### CROSS-REFERENCE TO RELATED APPLICATIONS

The present disclosure is a continuation of the PCT Application No. PCT/CN2023/122452, filed on Sep. 28, 2023, the disclosure of which is based on and claims priority to CN application No. 202211204121.9, filed on Sep. 29, 2022. The entire disclosure of the prior applications are hereby incorporated by reference in their entireties.

### TECHNICAL FIELD

Embodiments of the present disclosure relate to encoding and decoding technology, and in particular, to an encoding method, decoding method, encoding apparatus, decoding apparatus, electronic device, and non-transitory storage medium.

### BACKGROUND

An encoder is a device that compiles, converts signals (e.g., bitstreams) or data into a form of signals that can be used for communication, transmission, and storage. In the related arts, in the case that an encoder encounters network packet loss, a packet loss concealment technique is usually adopted to recover the lost data packet.

### SUMMARY

In a first aspect, some embodiments of the present disclosure provide an encoding method, including: obtaining at least two multiple description signals according to a to-be-coded signal, the at least two multiple description signals including a first multiple description signal and a second multiple description signal; performing first quantization on the first multiple description signal to obtain a first candidate quantized signal set, and performing second quantization on the second multiple description signal to obtain a second candidate quantized signal set; obtaining a first quantized signal corresponding to the first multiple description signal and a second quantized signal corresponding to the second multiple description signal according to the first candidate quantized signal set and the second candidate quantized signal set; and encoding the first quantized signal and the second quantized signal to generate a target bitstream corresponding to the to-be-coded signal.

In some embodiments, determining the to-be-coded signal as a multiple description signal of the to-be-coded signal, the number of the multiple description signals being at least two; quantizing each of the multiple description signals respectively to obtain a candidate quantized signal set; obtaining a quantized signal corresponding to each multiple description signal according to each candidate quantized signal set; and encoding each quantized signal to generate a target bitstream of the to-be-coded signal, where the target bitstream includes indication information which indicates whether the target bitstream is a multiple description stream.

In a second aspect, some embodiments of the present disclosure provide a decoding method, including: obtaining a quantized signal from a received target bitstream, where the quantized signal includes at least one of a first quantized signal or a second quantized signal, the first quantized signal is obtained by performing first quantization on a first multiple description signal, the second quantized signal is obtained by performing second quantization on a second multiple description signal, and the first multiple description signal and the second multiple description signal are obtained from a same signal; and obtaining a decoded signal based on at least one of the first quantized signal or the second quantized signal.

In some embodiments, obtaining at least one quantized signal from the received target bitstream, where the target bitstream includes indication information which indicates whether the target bitstream is a multiple description stream; and obtaining the decoded signal based on the indication information and the obtained quantized signal.

In a third aspect, some embodiments of the present disclosure provide an encoding apparatus, including: a determining module configured to, obtain at least two multiple description signals according to a to-be-coded signal, the at least two multiple description signals including a first multiple description signal and a second multiple description signal; a quantizing module configured to, perform first quantization on the first multiple description signal to obtain a first candidate quantized signal set, and perform second quantization on the second multiple description signal to obtain a second candidate quantized signal set; obtain a first quantized signal corresponding to the first multiple description signal and a second quantized signal corresponding to the second multiple description signal according to the first candidate quantized signal set and the second candidate quantized signal set; and an encoding module configured to, encode the first quantized signal and the second quantized signal to generate a target bitstream corresponding to the to-be-coded signal.

In some embodiments, the determining module is configured to determine the to-be-coded signal as a multiple description signal of the to-be-coded signal, the number of the multiple description signals is at least two; the quantizing module is configured to quantize each of the multiple description signals respectively to obtain a candidate quantized signal set; obtain a quantized signal corresponding to each multiple description signal according to each candidate quantized signal set; and the encoding module is configured to encode each quantized signal to generate a target bitstream of the to-be-coded signal, where the target bitstream includes indication information which indicates whether the target bitstream is a multiple description stream.

In a fourth aspect, some embodiments of the present disclosure provide a decoding apparatus, including: a first obtaining module configured to, obtain a quantized signal from a received target bitstream, where the quantized signal includes at least one of a first quantized signal or a second quantized signal, the first quantized signal is obtained by performing first quantization on a first multiple description signal, the second quantized signal is obtained by performing second quantization on a second multiple description signal, and the first multiple description signal and the second multiple description signal are obtained from a same signal; and a second obtaining module configured to, obtain a decoded signal based on at least one of the first quantized signal or the second quantized signal.

In some embodiments, the first obtaining module is configured to obtain at least one quantized signal from the received target bitstream, where the target bitstream includes indication information which indicates whether the target bitstream is a multiple description stream; and the second obtaining module is configured to obtain the decoded signal based on the indication information and the obtained quantized signal.

In a fifth aspect, some embodiments of the present disclosure further provide an electronic device including: one or more processing apparatus; and a storage apparatus configured to store one or more programs, which when executed by the one or more processing apparatus, cause the one or more processing apparatus to implement an encoding method or a decoding method as provided by the embodiments of the present disclosure.

In a sixth aspect, some embodiments of the present disclosure further provide a non-transitory storage medium including computer-executable instructions, which when executed by a computer processor, perform an encoding method or a decoding method as provided by the embodiments of the present disclosure.

### BRIEF DESCRIPTION OF THE DRAWINGS

The above and other features, advantages, and aspects of the embodiments of the present disclosure will become more apparent by referring to the following DETAILED DESCRIPTION and taken in conjunction with the accompanying drawings. Throughout the drawings, the same or similar reference numbers refer to the same or similar elements. It should be understood that the drawings are schematic and that components and elements are not necessarily drawn to scale.

FIG. 1 is a schematic flowchart of an encoding method provided in some embodiments of the present disclosure;

FIG. 2a is a schematic flowchart of another encoding method provided in some embodiments of the present disclosure;

FIG. 2b is a schematic structural diagram of an encoding apparatus provided in some embodiments of the present disclosure;

FIG. 3 is a schematic flowchart of a decoding method provided in some embodiments of the present disclosure;

FIG. 4 is a schematic flowchart of another decoding method provided in some embodiments of the present disclosure;

FIG. 5 is a schematic structural diagram of an encoding apparatus provided in some embodiments of the present disclosure;

FIG. 6 is a schematic structural diagram of a decoding apparatus provided in some embodiments of the present disclosure;

FIG. 7 is a schematic structural diagram of an electronic device provided in some embodiments of the present disclosure.

### DETAILED DESCRIPTION

The embodiments of the present disclosure will be described in more detail below with reference to the accompanying drawings. While certain embodiments of the present disclosure are shown in the drawings, it should be understood that the present disclosure may be implemented in various forms and should not be construed as limited to the embodiments set forth herein, but rather are provided for a more complete and thorough understanding of the present disclosure. It should be understood that the drawings and the embodiments of the present disclosure are for illustration purposes only and are not intended to limit the scope of the present disclosure.

It should be understood that the various steps recited in method embodiments of the present disclosure may be performed in a different order, and/or performed in parallel. Moreover, the method embodiments may include additional steps and/or omit performing the illustrated steps. The scope of the present disclosure is not limited in this respect.

The term “include” and variations thereof as used herein are intended to be open-ended, i.e., “including but not limited to”. The term “based on” is “based at least in part on”. The term “one embodiment” means “at least one embodiment”; the term “another embodiment” means “at least one additional embodiment”; the term “some embodiments” means “at least some embodiments”. Relevant definitions for other terms will be given in the following description.

It should be noted that the terms “first”, “second”, and the like in the present disclosure are only used for distinguishing different apparatus, modules or units, and are not used for limiting the order or interdependence of the functions performed by the apparatus, modules or units.

It is noted that references to “a” or “an” in this disclosure are intended to be illustrative rather than limiting, and that those skilled in the art will appreciate that references to “one or more” unless the context clearly indicates otherwise.

The names of messages or information exchanged between apparatus in the embodiments of the present disclosure are for illustrative purposes only, and are not intended to limit the scope of the messages or information.

It is understood that, before the technical solutions disclosed in the embodiments of the present disclosure are used, the user should be informed of the type, use range, use scene, etc. of the personal information related to the present disclosure in a proper manner according to relevant laws and regulations and the authorization of the user is obtained.

For example, in response to receiving a user's active request, a prompt message is sent to the user to explicitly prompt the user that the requested operation to be performed would require acquisition and use of personal information to the user. Thus, the user can autonomously select whether to provide personal information to software or hardware such as an electronic device, an application program, a server, or a non-transitory storage medium that performs the operations of the technical solution of the present disclosure, according to the prompt message.

As an alternative but non-limiting implementation, in response to receiving an active request from the user, the manner of sending the prompt message to the user may be, for example, a pop-up window, and the prompt message may be presented in a text manner in the pop-up window. In addition, a selection control for the user to select to “agree” or “disagree” to provide personal information to the electronic device, can be carried in the pop-up window.

It is understood that the above informing and obtaining user authorization process is only illustrative and is not intended to limit the implementation of the present disclosure, and other ways of satisfying the relevant laws and regulations may be applied to the implementation of the present disclosure.

It will be appreciated that the data referred to in this disclosure, including but not limited to the data itself, the acquisition or use of the data, should comply with the requirements of the applicable laws and regulations and related provisions.

As mentioned previously, the audio quality recovered using the packet loss concealment technique is poor compared to the audio quality of the normally decoded frames. Therefore, it is a technical problem to be solved to improve a packet loss resistance of the encoding apparatus.

The present disclosure provides an encoding method, decoding method, encoding apparatus, decoding apparatus, electronic device, and non-transitory storage medium to improve the packet loss resistance of the encoding apparatus.

The voice audio encoder includes a single-bitstream encoder, that is, for one frame of input signal, the encoder has only one output bitstream. For example, encoders established by a plurality of organizations for standardization are all single-bitstream encoders, including commonly used Opus encoders. In the case that such encoders encounter network packet loss, the lost data packet can only be recovered by adopting the packet loss concealment technique, and the quality of the recovered voice audio is poorer than that of the normally decoded frames.

In order to improve the packet loss resistance of the encoder to the network, a Multiple Description Coding (MDC) technology may be adopted. That is, for one frame of input signal, the encoder outputs at least more than 2 bitstreams, as the name implies. In the case that network packet loss occurs, any one of multiple bitstreams of the current frame can complete a normal decoding process after being received, which can well relieve the network packet loss to a certain extent. The number of times of calling the packet loss concealment technique is reduced, and the decoding quality of the voice audio is improved.

In the present disclosure, the bitstream structure of the multiple description encoder is designed into a bitstream format compatible with the set single-bitstream encoder, so that the application scene of the multiple description encoder is greatly expanded.

In the field of audio coding, a typical multiple description encoding method is to interleave and classify an input signal according to odd and even samples, then respectively provide a signal composed of the odd or even samples to a standard single-bitstream encoder for coding, and to combine signals decoded by two single-bitstream decoders at the decoding end to recover the complete signal, which can guarantee a single bitstream to be correctly decoded by the single-bitstream decoder and also improves the packet loss resistance of the encoder. However, the signal synthesized in this way has a poor decoding quality and sometimes has noise, and the quality of the signal-stream decoding is not good. Correspondingly, there is a method to perform interleaving and classification in a parameter domain, which can obtain better decoding quality, but has no way of guaranteeing that the bitstream format is consistent with the bitstream format of the single-bitstream decoder.

The embodiments of the present disclosure involve: determining a to-be-coded signal as a multiple description signal of the to-be-coded signal; quantizing each multiple description signal respectively to obtain a candidate quantized signal set; obtaining a quantized signal corresponding to each multiple description signal according to each candidate quantized signal set; and encoding each quantized signal to generate a target bitstream of the to-be-coded signal, where the target bitstream includes indication information which indicates whether the target bitstream is a multiple description bitstream. The present disclosure directly determines the to-be-coded signal as at least two multiple description signals of the to-be-coded signal, so that encoding of each multiple description signal is encoding of the to-be-coded signal, improving the packet loss resistance capability of the encoding apparatus.

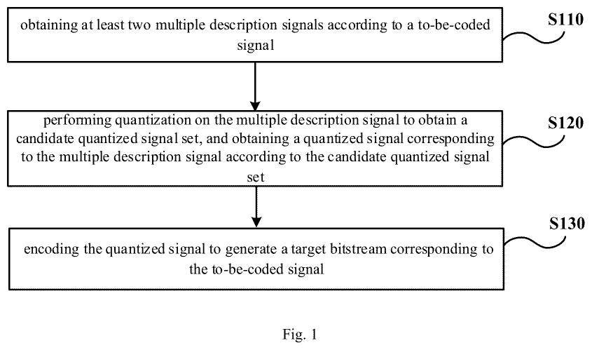

To solve the above technical problem, FIG. 1 is a schematic flowchart of an encoding method provided in some embodiments of the present disclosure, where the embodiment of the present disclosure is suitable for improving the packet loss resistance of an encoding apparatus, and the encoding apparatus may be an audio encoder and/or a video encoder. The method may be performed by the encoding apparatus, which may be implemented in the form of software and/or hardware, and optionally, implemented by an electronic device, which may be a mobile terminal, a PC terminal, a server, or the like.

As shown in FIG. 1, the encoding method may include steps S110 to S130.

S110, obtaining at least two multiple description signals according to a to-be-coded signal, the at least two multiple description signals including a first multiple description signal and a second multiple description signal. For example, the to-be-coded signal may be determined as a multiple description signal of the to-be-coded signal.

For example, a to-be-coded signal may be understood as a signal to be encoded. The to-be-coded signal may be considered to be a signal composed of at least one sample, the to-be-coded signal including at least one sample corresponding to audio, video, or image. The to-be-coded signal may be a residual signal to be quantized, and a plurality of samples in the to-be-coded signal are sequentially quantized and coded. For convenience of description, a sample r_Q10 in the residual signal to be quantized is taken as an example to describe the quantization process, and the quantization process of other samples is similar and will not be described again. In the present embodiment, the to-be-coded signal may be interpreted as a signal corresponding to one sample in the to-be-coded signal. Different samples are quantized similarly.

For example, the multiple description signal may be considered as a signal determined based on the to-be-coded signal. This step may directly determine the to-be-coded signal as a multiple description signal. The number of the multiple description signals is at least two, each multiple description signal being equal to the to-be-coded signal. Acceptable content, such as audio, video, or image, can be recovered based on each multiple description signal. The quality of content recovery depends only on the number of descriptions, i.e. the more the multiple description signals, the higher the quality of the content obtained by decoding.

For example, the to-be-coded signal may be directly taken as the multiple description signal, so that in the case that the multiple description signal is encoded subsequently, the to-be-coded signal is encoded, that is, the encoding of each multiple description signal is the encoding of the to-be-coded signal.

S120, performing first quantization on the first multiple description signal to obtain a first candidate quantized signal set, and performing second quantization on the second multiple description signal to obtain a second candidate quantized signal set; and obtaining a first quantized signal corresponding to the first multiple description signal and a second quantized signal corresponding to the second multiple description signal according to the first candidate quantized signal set and the second candidate quantized signal set. For example, respectively quantizing each of the multiple description signals to obtain a candidate quantized signal set; and obtaining a quantized signal corresponding to each multiple description signal according to each candidate quantized signal set.

For example, the candidate quantized signals in the candidate quantized signal set may be regarded as quantized signals obtained by quantizing the multiple description signals. The quantized signal corresponding to the multiple description signal may be a finally determined quantized signal of the multiple description signal.

For example, each multiple description signal may be respectively quantized to obtain a plurality of candidate quantized signal sets, and then a quantized signal corresponding to each multiple description signal may be obtained according to each candidate quantized signal set.

For example, in the case that a multiple description signal is quantized to obtain a plurality of candidate quantized signal sets, different quantization processes may be used, for example, a candidate quantized signal included in one of the candidate quantized signal set is determined by rounding up, a candidate quantized signal in another candidate quantized signal set is determined by rounding down, and a candidate quantized signal in still another candidate quantized signal set is determined by adding random quantization noise. In the step, in the case that each multiple description signal is quantized, a quantization mode of a set encoding apparatus can be adopted for quantization; the set encoding apparatus can be regarded as an encoding apparatus to be compatible, the set encoding apparatus is not limited and can be a single-bitstream encoding apparatus, and the single-bitstream encoding apparatus can be regarded as an encoding apparatus which generates a single bitstream after encoding. The quantization mode may be considered as a mode of quantizing a signal. For example, the set encoding apparatus is an Opus encoding apparatus, and the quantization mode is Noise Shaping Quantizer (NSQ).

For example, after obtaining the multiple description signals, the multiple description signals may be quantized by using the quantization mode of the set encoding apparatus, to obtain a candidate quantized signal set corresponding to each multiple description signal.

For example, in this step, in the case that each multiple description signal is quantized, the quantization may be performed separately to obtain a quantized signal corresponding to each multiple description signal. For example, the multiple description signal is quantized to obtain at least one candidate quantized signal set, and then one candidate quantized signal is directly selected from the candidate quantized signals in the at least one candidate quantized signal set, to be determined as the quantized signal corresponding to the multiple description signal. In the case that the number of the candidate quantized signal set corresponding to one multiple description signal is one, the candidate quantized signals in the candidate quantized signal set can be directly determined as the quantized signal of the multiple description signal. In the case that the multiple description signal corresponds to at least two candidate quantized signal sets, a candidate quantized signal with a minimum quantization error may be selected from the candidate quantized signals in the candidate quantized signal set, as the quantized signal of the multiple description signal.

In some embodiments, a plurality of candidate quantized signal combinations of the to-be-coded signal are obtained according to the first candidate quantized signal set and the second candidate quantized signal set, each candidate quantized signal combination of the plurality of candidate quantized signal combinations including a plurality of candidate quantized signals obtained according to the first candidate quantized signal in the first candidate quantized signal set and the second candidate quantized signal in the second candidate quantized signal set; one candidate quantized signal combination is selected from the plurality of candidate quantized signal combinations as a target quantized signal combination of the to-be-coded signal; and a first quantized signal is determined according to the first candidate quantized signal corresponding to the target quantized signal combination, and a second quantized signal is determined according to the second candidate quantized signal corresponding to the target quantized signal combination.

In some embodiments, the first candidate quantized signal set includes one or more first candidate quantized signals and the second candidate quantized signal set includes one or more second candidate quantized signals.

For example, in the case that the first candidate quantized signal set includes one first candidate quantized signal and the second candidate quantized signal set includes one second candidate quantized signal, the candidate quantized signal combination is determined according to the one first candidate quantized signal and the one second candidate quantized signal; and the quantized signal is determined according to the candidate quantized signal combination.

For example, in a case where the first candidate quantized signal set includes a plurality of first candidate quantized signals and the second candidate quantized signal set includes a plurality of second candidate quantized signals, the plurality of candidate quantized signal combinations are determined according to the plurality of first candidate quantized signals and the plurality of second candidate quantized signals; and a candidate quantized signal combination is selected from the plurality of candidate quantized signal combinations for determining the quantized signal.

For example, the candidate quantized signal combination with the minimum quantization error in the plurality of candidate quantized signal combinations is selected as the target quantized signal combination.

For example, in the case that the multiple description signals are quantized, the quantization may be integrated to obtain the quantized signal corresponding to each multiple description signal. During integrated quantization, the quantized signal corresponding to each multiple description signal can be selected in conjunction with a global quantization error minimization principle, so as to reduce the quantization error.

For example, the global quantization error minimization principle may be understood as a quantization error minimization principle globally. For example, for each multiple description signal, quantization is performed respectively by using the quantization mode of the set encoding apparatus, to obtain at least two corresponding candidate quantized signal sets, and candidate quantized signals in the candidate quantized signal set corresponding to each multiple description signal may be combined with each other (the combination is not limited, as long as it is ensured that a decoding end uses the same during decoding), so as to obtain a candidate quantized signal combination corresponding to the to-be-coded signal. Globally, it may be considered that, for each multiple description signal, a candidate quantized signal in the candidate quantized signal set with a minimum corresponding error is selected as the quantized signal of the corresponding multiple description signal.

For example, a value with the minimum quantization error with respect to the to-be-coded signal is selected from a candidate quantized signal combination corresponding to the to-be-coded signal, so as to determine a candidate quantized signal in a candidate quantized signal set forming the candidate quantized signal combination as a quantized signal of the corresponding multiple description signal.

For another example, based on the global quantization error minimization principle, if a weighted sum of a quantization error of a candidate quantized signal selected from a candidate quantized signal combination corresponding to the to-be-coded signal with respect to the to-be-coded signal, and a quantization error of a candidate quantized signal in a candidate quantized signal set forming the candidate quantized signal combination with respect to the corresponding multiple description signal, is minimum in weighted sums corresponding to all candidate quantized signal combinations, the candidate quantized signal in the candidate quantized signal set corresponding to the candidate quantized signal combination is determined as the quantized signal of the corresponding multiple description signal.

For example, the present embodiment does not limit the specific quantization mode, as long as the quantization mode of the multiple description signal is consistent with the quantization mode of the set encoding apparatus. For example, the same quantization mode may include the same random seed updating method and the same multiple description signal updating method.

In one embodiment, this step may obtain two candidate quantized signal sets of the multiple description signal by using a rate distortion cost, and select a candidate value that minimizes the rate distortion cost as the quantized signal of the multiple description signal.

S130, encoding the first quantized signal and the second quantized signal to generate a target bitstream corresponding to the to-be-coded signal. For example, each quantized signal is encoded to generate a target bitstream of the to-be-coded signal.

In some embodiments, the target bitstream includes indication information which indicates whether the target bitstream is a bitstream generated based on the at least two multiple description signals.

For example, the target bitstream includes indication information which indicates whether the target bitstream is a multiple description bitstream (i.e., a bitstream generated according to at least two multiple description signals).

In some embodiments, in the case that the quantized signal included in the target bitstream is determined based on the multiple description signal, the target bitstream may include indication information which indicates that the target bitstream is the multiple description bitstream.

In some embodiments, in the case that the multiple description signal of the to-be-coded signal is used to generate the target bitstream, the target bitstream includes indication information which indicates that the target bitstream is the multiple description bitstream.

For example, the encoding method of the present disclosure may include indication information within the target bitstream, for indicating whether the target bitstream is a multiple description bitstream. In the case that the multiple description signal is not used for encoding, the indication information may indicate that the target bitstream is not a multiple description bitstream.

For example, the multiple description bitstream may be considered as a bitstream generated based on multiple description signal encoding.

For example, a packing mode of the set encoding apparatus may be adopted to encode each quantized signal, to generate a target bitstream. The packing mode may be considered as a mode of packing the bitstream, and the packing mode defines a bitstream format of the packed bitstream, such as a position of the quantized signal in the target bitstream. The target bitstream can be regarded as a bitstream generated after encoding. The number of the target bitstream may be at least one. The number of the target bitstream may be the same as or less than the number of the multiple description signals.

For example, in the case that the quantized signal is encoded to generate the target bitstream, the quantized signal may be packed into the target bitstream. Each quantized signal can be packed into different target bitstreams respectively. Here, the position of the quantized signal in the target bitstream is not limited. The quantized signal corresponding to the to-be-coded signal can be packed into at least two target bitstreams. Therefore, decoding can be realized only by receiving one target bitstream, and the more the received target bitstreams, the higher the decoding quality, thereby improving the packet loss resistance of the encoding apparatus.

For example, the specific packing mode is not limited in this step, and different quantized signals may be packed into different target bitstreams, or at least two quantized signals may be packed into one target bitstream.

For example, the bitstream format of the target bitstream is the same as the bitstream format of the set encoding apparatus, and the encoding apparatus capable of executing the encoding method of the present disclosure is compatible with the set encoding apparatus.

In some embodiments, the target bitstream includes a first random seed and a second random seed. For example, the target bitstream includes an initial first random seed and an initial second random seed.

For example, Table 1 is a bitstream format of a target bitstream provided in some embodiments of the present disclosure. Referring to Table 1, a plurality of table entries may also be included above a row where Random seed is located in the table, which is not limited herein, and the present disclosure only expands content associated with the present disclosure; in the case that the quantized signal is packed, content (such as amplitude, sign) related to the quantized signal may be packed to Amplitude of excitation signal and Sign of excitation signal in Table 1. In the case that encoding the to-be-coded signal, in response to a random seed being used, the random seed may be packed to Random seed in Table 1. The bitstream format shown in Table 1 may be a bitstream structure of the set encoding apparatus, and a sequence of each field in the bitstream may be the same as the sequence shown in the table.

TABLE 1
Bitstream format of a target bitstream provided
in some embodiments of this disclosure

. . .
Random seed
. . .
. . .
. . .
Amplitude of excitation signal
Sign of excitation signal

According to the technical solution of the embodiment of the present disclosure, the to-be-coded signal is directly determined to be at least two multiple description signals of the to-be-coded signal, so that encoding of each multiple description signal is encoding of the to-be-coded signal, which improves the packet loss resistance of the encoding apparatus. In the case that the target bitstream is obtained by the encoding, the bitstream format of the target bitstream can be the same as the bitstream format of the set encoding apparatus, enabling the encoding apparatus of the present disclosure to be compatible with the set encoding apparatus. The encoding apparatus and the decoding apparatus in the related art exist correspondingly, so that it is only needed to determine mutually the corresponding encoding and decoding methods, without considering compatibility. In the present disclosure, indication information is introduced since compatibility is considered, and in the case that the encoding apparatus of the present disclosure is interworked with the set encoding apparatus, the indication information included in the target bitstream can be used for indicating whether the target bitstream is a multiple description bitstream, so as to indicate the decoding method of the encoding apparatus, ensuring the compatibility of the encoding apparatus of the present disclosure with the set encoding apparatus.

For example, in the case that the target bitstream is encoded, a multiple description signal is generated, and in the case that the target bitstream is generated based on the multiple description signal, the quantization mode and the packing mode the same as those of the set encoding apparatus can be adopted, improving the compatibility of the target bitstream with the set encoding apparatus, and enriching application scenes of the target bitstream; in addition, due to the fact that a plurality of multiple description signals are generated, a plurality of target bitstreams can be obtained, improving the packet loss resistance of the encoding apparatus.

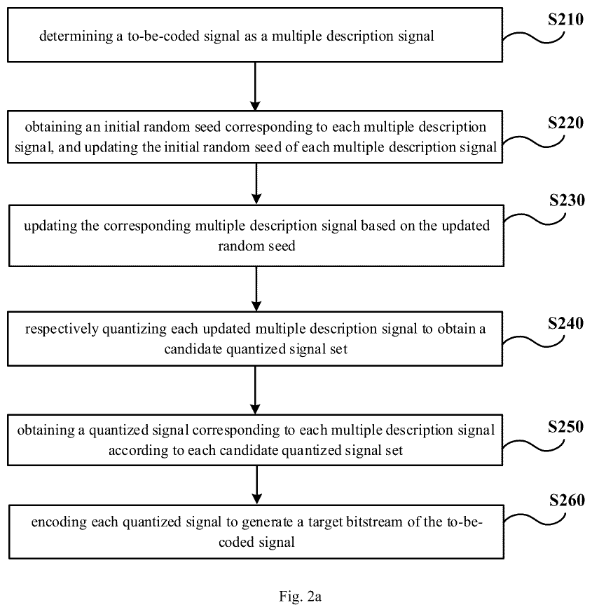

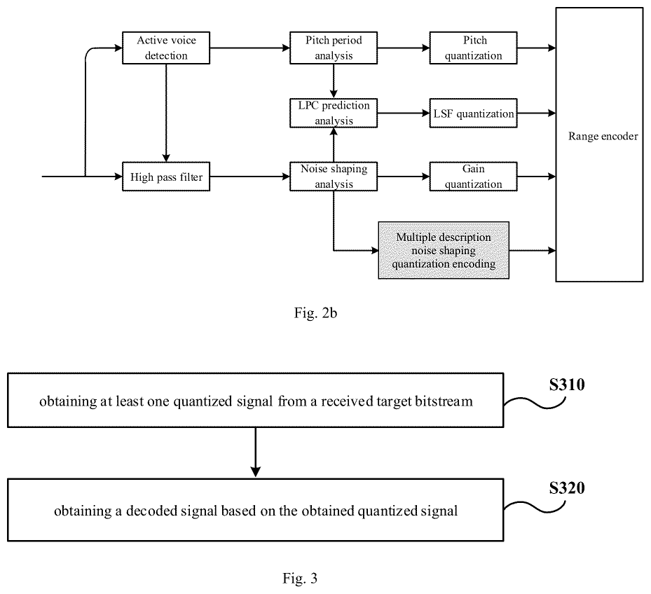

FIG. 2a is a schematic flowchart of another encoding method provided in some embodiments of the present disclosure, and this embodiment exemplarily describes a technical means for quantizing a multiple description signal. Referring to FIG. 2a, the method includes steps S210 to S260.

In S210, determining a to-be-coded signal as a multiple description signal.

For example, in the embodiment, in the case that the multiple description signal is obtained, the to-be-coded signal is directly taken as the multiple description signal, so as to be better compatible with the set encoding apparatus.

In S220, obtaining an initial random seed corresponding to each multiple description signal, and updating the initial random seed of each multiple description signal.

For example, in this embodiment, each multiple description signal corresponds to an initial random seed. In the case that quantizing the multiple description signal, the random seed may be updated to obtain an updated random seed.

For example, in the case that the random seed is updated, a random seed updating method may be used for the updating.

For example, the random seed updating method may be considered as a method for updating the random seed, and the specific updating mode is not limited herein, and the initial random seed may be updated by using an updating method of the set encoding apparatus in the encoding of the present embodiment.

For example, to make the quantization error more whitened, a random seed is generally added in the quantization process, and the seed is generally initialized to an initial value before starting quantization, for example: 0. 1, 2 or 3. It should be noted that, adding a random seed in the quantization process is not an essential operation, and the quantization of NSQ in the Opus encoding apparatus uses the implementation of seed, reducing the quantization noise, and improving the compression efficiency.

The to-be-coded signal in the present disclosure may include one sample or may include a plurality of samples. In the case that the to-be-coded signal includes a plurality of samples, the samples can be quantized respectively, and each sample is quantized equally, with the only exception that different samples have different initial random seed values.

For example, in the case that the to-be-coded signal includes a plurality of samples, the signal corresponding to each sample may be regarded as the to-be-coded signal.

For example, for a first quantized sample, the initial random seed may be an initial value, and the initial random seed of a subsequent quantized sample may be a random seed updated by a previous quantized sample.

In S230, updating the corresponding multiple description signal based on the updated random seed.

In some embodiments, first quantization is performed on a first multiple description signal according to a first random seed corresponding to the first multiple description signal, and second quantization is performed on a second multiple description signal according to a second random seed corresponding to the second multiple description signal.

For example, the first random seed includes an initial first random seed and an updated first random seed. Obtaining the initial first random seed; updating the initial first random seed to obtain the updated first random seed; updating the first multiple description signal based on the updated first random seed to obtain an updated first multiple description signal; and performing first quantization on the updated first multiple description signal to obtain a first candidate quantized signal set.

For example, the second random seed includes an initial second random seed and an updated second random seed. Obtaining the initial second random seed; updating the initial second random seed to obtain the updated second random seed; updating the second multiple description signal based on the updated second random seed to obtain an updated second multiple description signal; and performing second quantization on the updated second multiple description signal to obtain a second candidate quantized signal set.

For example, the multiple description signal may be updated using a multiple description signal updating method. The multiple description signal updating method may be regarded as a method of updating a multiple description signal. At the time of updating, the updating may be based on a random seed. Each multiple description signal may correspond to a random seed. In the updating, the multiple description signal updating method may be determined based on a size of the random seed. Different set encoding apparatuses may correspond to different multiple description signal updating methods, which is not limited herein.

For example, in the case that the random seed is less than zero, the corresponding multiple description signal may be inverted. The multiple description signal may not be inverted in the case that the random seed is not less than zero. Here, zero is merely an example, and it may be any value. Inversion can be considered as one of updating means.

In the above embodiments, updating the multiple description signal can effectively reduce quantization noise.

In S240, respectively quantizing each updated multiple description signal to obtain a candidate quantized signal set.

For example, after updating the multiple description signal, in the step, a quantization mode of the set encoding apparatus may be adopted to quantize the updated multiple description signal, to obtain a candidate quantized signal set.

In S250, obtaining a quantized signal corresponding to each multiple description signal according to each candidate quantized signal set.

For example, after determining the candidate quantized signal set corresponding to each multiple description signal, this step can select the corresponding quantized signal from at least two candidate quantized signal sets corresponding to each multiple description signal.

For example, the technical means for selecting the quantized signal corresponding to each multiple description signal is not limited herein. For example, the quantized signal corresponding to each multiple description signal may be determined based on a quantization error of each multiple description signal with respect to a candidate quantized signal in the corresponding candidate quantized signal set, and a quantization error thereof with respect to a corresponding candidate quantized signal combination. The manner of determining the quantization error is not limited, such as based on Mean Square Error. The technical means for determining the corresponding candidate quantized signal combination is not limited, and it may be determined by performing mathematical operations, such as combination operations, on candidate quantized signals in the candidate quantized signal set corresponding to the multiple description signal, to obtain the candidate quantized signal combination.

Illustratively, at least one candidate quantized signal is selected from the candidate quantized signal set of each multiple description signal respectively, and a mathematical operation is performed on the selected candidate quantized signal to obtain a candidate quantized signal combination corresponding to the signal to be quantized. Continue to respectively select an unselected candidate quantized signal from the candidate quantized signal set of each multiple description signal, for determining the candidate quantized signal combination of the corresponding signal to be quantized, until the candidate quantized signals are all selected, and select a target quantized signal corresponding to the signal to be quantized from each candidate quantized signal combination corresponding to the signal to be quantized.

For example, after obtaining the target quantized signal, the random seed may be continuously updated to serve as the initial random seed of the next sample, and in the case that the random seed is updated this time, based on the random seed updated in the S220 and the updating of the quantized signal of the corresponding multiple description signal, for example, a sum of the random seed updated in the S220 and the quantized signal of the corresponding multiple description signal may be subjected to 32-bit overflow protection function processing, to obtain an updated random seed, which is taken as the initial random seed of the next sample.

In one embodiment, the obtaining a quantized signal corresponding to each multiple description signal according to each candidate quantized signal set, includes:
for example, obtaining a plurality of candidate quantized signal combinations of the to-be-coded signal according to each candidate quantized signal set, where the candidate quantized signal combinations are combinations of candidate quantized signals in candidate quantized signal sets corresponding to different multiple description signals; selecting a candidate quantized signal combination from each candidate quantized signal combination as a target quantized signal of the to-be-coded signal according to a set selection method, where the set selection method includes a method of using a candidate quantized signal combination with a minimum quantization error in the candidate quantized signal combinations as a target quantized signal of the to-be-coded signal; and determining a candidate quantized signal in the candidate quantized signal set corresponding to the target quantized signal as the quantized signal corresponding to each multiple description signal.

For example, the candidate quantized signal combination may be considered a candidate quantized signal of the to-be-coded signal. The target quantized signal may be understood as a finally determined quantized signal of the to-be-coded signal.

For example, after determining the candidate quantized signal set corresponding to each multiple description signal, in the present embodiment, the candidate quantized signals in the candidate quantized signal set corresponding to each multiple description signal or the candidate quantized signals in the updated candidate quantized signal set may be combined, to obtain the candidate quantized signal combination of the to-be-coded signal. In the case that the candidate quantized signal combination is obtained by the combining, each candidate quantized signal combination may include the candidate quantized signals in at least one candidate quantized signal set corresponding to each multiple description signal. The combining method is not limited, and different operation methods can be adopted to perform mathematical operation, such as a mean or a weighted sum.

Illustratively, the multiple description signals are r1_Q10 and r2_Q10, and the two multiple description signals are quantized respectively, to obtain 2 candidate quantized signals rq11_pulse and rq12_pulse of r1_Q10, and two candidate quantized signals rq21_pulse and rq22_pulse of r2_Q10. The signals obtained after updating the candidate quantized signals in the candidate quantized signal sets corresponding to the multiple description signals r1_Q10 and r2_Q10 are combined, to obtain a candidate quantized signal combination.

For example, rq11_pulse is selected from the candidate quantized signal set corresponding to r1_Q10, rq12_pulse is selected from the candidate quantized signal set corresponding to r2_Q10, the two candidate quantized signals are updated and combined to obtain a candidate quantized signal combination rq_pulse1=(srq11_pulse+srq21_pulse)/2, where rq_pulse1 is the candidate quantized signal combination corresponding to the to-be-coded signal.

For example, rq_pulse1 can also be obtained by a combination of:

$$rq\_pulse 1 = srq 11 \_pulse + srq 21 \_pulse ; or$$

$$rq\_pulse 1 = alpha * srq 11 \_pulse + ( 1 - alpha ) srq 21 \_pulse .$$

For example, the technical means for determining the candidate quantized signal combination is not limited here, as long as the technical means is consistent at both the encoding and decoding ends. In the case that determining the candidate quantized signal combination, in response to the following formula being used, the decoding end also needs to use the following formula in the case that decoding the target bitstream: rq_pulse1=(srq11_pulse+srq21_pulse)/2.

For example, in the case that selecting a target quantized signal from the candidate quantized signal combination, the selection may be made according to a set selection method, where the set selection method is not limited, such as random selection, or based on a quantization error.

In one embodiment of the present disclosure, the selection may be made based on a minimum error principle. The set selection method includes taking a candidate quantized signal combination with a minimum quantization error in the candidate quantized signal combinations as a target quantized signal of the to-be-coded signal, and in the case that making the selection using the set selection method, an error value corresponding to each candidate quantized signal combination can be determined, a minimum value is selected from the error values, and the candidate quantized signal combination corresponding to the minimum error value is taken as the target quantized signal.

For example, each candidate quantized signal combination may correspond to a quantization error, which may be determined based on the quantization errors of the candidate quantized signal combination and the to-be-coded signal, and the quantization errors before and after the quantization of each multiple description signal. For example, a sum or weighted sum of the quantization errors of the candidate quantized signal combination and the to-be-coded signal, and the quantization errors before and after the quantization of each multiple description signal, is determined as the quantization error corresponding to the candidate quantized signal combination.

Illustratively, weighted values of an error of the candidate quantized signal combination rq_pulse1 with respect to the to-be-coded signal, an error of rq11_pulse with respect to r1_Q10, and an error of rq21_pulse with respect to r2_Q10 may be determined as the error values corresponding to the candidate quantized signal combination rq_pulse1. A candidate quantized signal combination with a minimum error value is selected from the error value corresponding to each candidate quantized signal combination as the target quantized signal.

For example, the candidate quantized signals in the candidate quantized signal set used for determining the target quantized signal may be considered as candidate quantized signals in the candidate quantized signal set corresponding to the target quantized signal, and for example, in response to the target quantized signal being rq_pulse1, the used candidate quantized signals in the candidate quantized signal set are rq11_pulse and rq21_pulse. The srq11_pulse and srq21_pulse are updated signals of rq11_pulse and rq21_pulse respectively, and the updating includes inversion.

For example, after the candidate quantized signals in the candidate quantized signal set used for the target quantized signal are determined, each candidate quantized signal in the used candidate quantized signal set is taken as the quantized signal of the corresponding multiple description signal. For example, rq11_pulse is taken as the quantized signal of the multiple description signal r1_Q10, and rq21_pulse is taken as the quantized signal of the multiple description signal r2_Q10. After one multiple description signal corresponds to candidate quantized signals in a plurality of candidate quantized signal sets, a mathematical operation may be performed on the corresponding candidate quantized signals in the plurality of candidate quantized signal sets, and the operation is not limited.

In S260, encoding each quantized signal to generate a target bitstream of the to-be-coded signal.

For example, the target bitstream includes indication information which indicates whether the target bitstream is a multiple description stream.

In the above embodiments, exemplary technical means for quantizing the multiple description signal are described, and in the case that the target bitstream is encoded, the multiple description signal is quantized by using a random seed, to reduce the quantization noised. For example, the quantization mode and the packing mode of the set encoding apparatus can be adopted for encoding, so that the bitstream format of the target bitstream is compatible with the bitstream format of the set encoding apparatus, and the random seed updating method and the multiple description signal updating method of the set encoding apparatus can be adopted to reduce the quantization noise of the target bitstream and improve the compression efficiency.

In some embodiments, the target bitstream includes a random seed corresponding to the quantized signal.

For example, in the case that the target bitstream is encoded, in response to a random seed being used, the used random seed may be packed to obtain the target bitstream, so that the receiving end decodes based on the random seed in the target bitstream. The position of the random seed in the target bitstream is not limited here, and the random seed corresponding to the quantized signal and the quantized signal can be packed into the same target bitstream.

For example, one multiple description signal may correspond to multiple random seeds, for example, one multiple description signal may correspond to an initial random seed and a random seed updated from the initial random seed. In the case that the random seed corresponding to the quantized signal is packed into the target bitstream, the initial random seed and/or the updated random seed can be packed into the target bitstream.

For example, in the case that encoding the to-be-coded signal, the initial random seed of the first quantized sample of the to-be-coded signal may be a predetermined value. The value of the initial random seed of the subsequent quantized sample may be the random seed updated by the previous quantized sample. In the case that each sample is quantized, the initial random seed needs to be updated, and after the updating is finished, the random seed needs to be updated again, so that the random seed updated again is taken as the initial random seed of the next sample.

In one embodiment, the random seed corresponding to the quantized signal is an initial random seed.

For example, each multiple description signal has an initial random seed, and in the case that the multiple description signal is quantized, the initial random seed needs to be updated, to update the multiple description signal based on the updated random seed, and then quantize the multiple description signal. The updated random seed may be updated again for use as the initial random seed for the next sample.

The encoding method provided by the present disclosure is exemplarily described below, and the encoding method of the present disclosure may be considered as a multiple description encoding method compatible with the set encoding apparatus, and aims to solve the problem that the bitstream structure of the multiple description encoding apparatus is inconsistent with the bitstream structure of a single-bitstream encoding apparatus, such as an Opus encoding apparatus, on the premise of improving the packet loss resistance. For the convenience of description, the Opus encoding apparatus is exemplified as a single-bitstream encoding apparatus, and the single-bitstream structure of the multiple description encoding apparatus is designed to be consistent with the Opus. The multiple description encoding apparatus designed in the way can be interworked with the Opus encoding apparatus, well overcoming the defect that the multiple description encoding apparatus cannot interwork with a single-bitstream encoding apparatus.

FIG. 2b is a schematic structural diagram of an encoding apparatus provided in some embodiments of the present disclosure. In the present disclosure, a to-be-coded signal can be outputted after noise shaping analysis, and the encoding method of the present disclosure can be integrated in a multiple description encoding noise shaping quantizing module.

For example, in order to keep the quantized signal obtained by the multiple description encoding method the same as the quantized signal of the single-bitstream encoding apparatus (e.g., Opus), in the case that performing quantization encoding on the input signal, it is necessary to adopt the same quantization mode as the single-bitstream encoding apparatus (i.e., the quantization mode of the set encoding apparatus) and the same bitstream generating method (i.e., the packing method of the set encoding apparatus).

Illustratively, the present disclosure provides a multiple description quantization mode compatible with the Opus encoding apparatus: for convenience of description, a sample r_Q10 in a residual signal to be quantized (i.e., a to-be-coded signal) is taken as an example to describe a quantization process, and other samples are quantized similarly, which will not be described again. The random seed is seed, and the purpose of adding seed in the quantization process is to whiten the quantization error. The number of multiple description codes is 2. In order to maintain compatibility with the Opus encoding apparatus, the coding format of each multiple description bitstream (i.e., the target bitstream) is completely consistent with that of the Opus encoding apparatus.

For example, the encoding of the encoding end includes the following steps:

1. Initializing a random seed value, e.g., seed=seed1=seed2=0. (i.e., obtaining an initial random seed corresponding to each multiple description signal, such as obtaining an initial random seed corresponding to a first sample).
where, seed1 and seed2 are random seeds corresponding to multiple description residual signals (i.e., multiple description signals) r1_Q10 and r2_Q10, respectively. The initial value may be 0, 1, or other specific values, and it should be noted that the initial value of the random seed will be also used at the decoding end, so it is necessary to ensure that the encoding and decoding ends maintain a one-to-one correspondence.

2. Obtaining the multiple description residual signals r1_Q10 and r2_Q10 according to the residual signal r_Q10;
where, the multiple description residual signal 1: r1_Q10=r_Q10; the multiple description residual signal 2: r2_Q10=r_Q10 (i.e., determining the to-be-coded signal to be a multiple description signal of the to-be-coded signal).

3. Updating a value of the random seed and inverting signs of the residual signals r1_Q10 and r2_Q10;

Updating the random seed (i.e. updating the initial random seed of each multiple description signal by using the random seed updating method of the set encoding apparatus) may be as follows:

$$seed 1 = rand ( seed 1 ) ;$$

$$seed 2 = rand ( seed 2 ) ;$$

$$rand ( x ) = overflow 32 ( 907633515 + x * 196314165 ) ;$$

for example, rand is a randomization function, overflow32 is a 32-bit overflow protection function, and overflow protection is performed in the case that the result of the addition exceeds 32 bits.

For example, inverting the residual signal (i.e. updating the corresponding multiple description signal based on the updated random seed by using the multiple description signal updating method of the set encoding apparatus) may be as follows.

For example, if the random seed seed1 of the multiple description residual signal 1 is smaller than 0, the multiple description residual signal 1 r1_Q10 is inverted to obtain −r1_Q10, which is taken as the updated multiple description residual signal 1; otherwise, the multiple description residual signal 1 is not inverted, and r1_Q10 is taken as the updated multiple description residual signal 1.

For example, if the random seed seed2 of the multiple description residual signal 2 is smaller than 0, the multiple description residual signal 2 is inverted to obtain-r2_Q10, which is taken as the updated multiple description residual signal; otherwise, the multiple description residual signal 2 is not inverted, and r2_Q10 is taken as the updated multiple description residual signal 2. 0 that is compared with the random seed in the above judgment is merely an example and is not limited.

For example, seed1 and seed2 are random seeds corresponding to r1_Q10 and r2_Q10, respectively. It should be noted that, here, the method of updating seed1 and seed2 (i.e. the random seed updating method), and the method of updating the residual signal using seed1 and seed2 (i.e. the multiple description signal updating method) are consistent with those of the Opus encoding apparatus, in order to ensure that the generated bitstream is completely consistent with the Opus, and the encoding and decoding quality is also equivalent to that of the Opus encoding apparatus.

4. The 2 multiple description residual signals are quantized respectively. The detailed quantization mode is not described herein, and it is assumed that the obtained optimal quantized signals (i.e. quantized signals corresponding to the multiple description signals) are: rq1_pulse and rq2_pulse.

For example, 2 candidate quantized signals rq11_pulse and rq12_pulse (i.e., candidate quantized signals in the candidate quantized signal set corresponding to the multiple description signal r1_Q10) are obtained according to r1_Q10, by using the quantization mode of NSQ in Opus (i.e., by using the quantization mode of the set encoding apparatus). Two candidate quantized signals rq21_pulse and rq22_pulse (i.e. candidate quantized signals in the candidate quantized signal set corresponding to the multiple description signal r2_Q10) are obtained according to r2_Q10, by using the same quantization mode as r1_Q10 (i.e. the multiple description signal r2_Q10 uses the quantization mode of the set encoding apparatus).

For example, 4 candidate quantized signals of r_Q10 (i.e., a candidate quantized signal combination), i.e., rq_pulse1, rq_pulse2, rq_pulse3, and rq_pulse 4, are obtained according to the candidate quantized signals of r1_Q10 and r2_Q10 (i.e., the candidate quantized signals in the candidate quantized signal set). Note that here, r1_Q10 and r2_Q10 are signals subjected to sign inversion, and r_Q10 is a to-be-coded signal without sign inversion. Based on the global quantization error minimization principle, the optimal quantized signal rq_pulse of r_Q10 (i.e., the target quantized signal of the to-be-coded signal) is obtained from the 4 candidate signals. The candidate quantized signal corresponding to rq_pulse is taken as the optimal quantized signal of r1_Q10 and r2_Q10 (i.e., the quantized signal corresponding to each multiple description signal). For example:

$$rq\_pulse 1 = ( srq 11 \_pulse + srq 21 \_pulse ) / 2$$

$$rq\_pulse 2 = ( srq 11 \_pulse + srq 22 \_pulse ) / 2$$

$$rq\_pulse 3 = ( srq 21 \_pulse + srq 21 \_pulse ) / 2$$

$$rq\_pulse 4 = ( srq 21 \_pulse + srq 22 \_pulse ) / 2$$

For example, srq11, srq12, srq21, and srq22 are signals after signs of rq11_pulse, rq12_pulse, rq21_pulse, and rq22_pulse are inverted respectively, and the sign inversion method can refer to step 5.

For example, based on the global quantization error minimization principle, it is assumed that the quantization error of rq_pulse4 is minimum, rq_pulse4 is taken as the optimal quantized signal rq_pulse of r_Q10 (i.e., selecting one candidate quantized signal from the candidate quantized signals of each candidate quantized signal combination as the target quantized signal of the to-be-coded signal). Then rq21_pulse (i.e., the candidate quantized signal in the candidate quantized signal set used for determining the target quantized signal, also referred to as the candidate quantized signal in the candidate quantized signal set corresponding to the target quantized signal) forming rq_pulse4 is taken as the optimal quantized signal of r1_Q10, and rq22_pulse (i.e., the candidate quantized signal in the candidate quantized signal set used for determining the target quantized signal, also referred to as the candidate quantized signal in the candidate quantized signal set corresponding to the target quantized signal) is taken as the optimal quantized signals rq1_pulse and rq2_pulse of r2_Q10.

5. Updating based on the quantized signals rq1_pulse and rq2_pulse, such as inverting the signs of the quantized signals srq1_pulse and srq2_pulse as follows (one of the set updating methods), to obtain updated quantized signals.

For example, if seed1 is smaller than 0, then −rq1_pulse is taken as the quantized signal after updating the multiple description signal 1; otherwise, rq1_pulse is taken as the quantized signal after updating the multiple description signal 1. If the seed2 is smaller than 0, −rq 2_pulse is taken as the quantized signal after updating the multiple description signal 2; otherwise, rq2_pulse is taken as the quantized signal after updating the multiple description signal 2.

6. Obtaining a true quantized signal value rq_pulse: rq_pulse=(srq1_pulse+srq2_pulse)/2, according to srq1_pulse and srq2_pulse, i.e., a mean of the inverted quantized signals is determined as the true quantized signal value. Here, rq_pulse is the signal before sign inversion.

For example, the true quantized signal value may be used in the case that obtaining the quantized signal of the multiple description signal, for determining the finally obtained quantized signal. For example, whether the quantization error meets the requirement is determined based on the magnitude of the true quantized signal value and the to-be-coded signal, e.g., whether a weighted sum of a difference between the true quantized signal value and the to-be-coded signal and a difference between each multiple description signal and the candidate quantized signal in the corresponding candidate quantized signal set, is smaller than a set value or is a minimum value of weighted sums corresponding to all multiple description signals, so as to determine the final quantized signal.

7. Respectively updating the corresponding random (seed values) to serve as initial random seeds of the next sample.

The updating is as follows:

$$seed 1 = overflow 32 ( seed 1 + rq 1 \_pulse ) ;$$

$$seed 2 = overflow 32 ( seed 2 + rq 2 \_pulse ) .$$

In this embodiment, the random seed may be updated by using a randomization function before the multiple description signal is quantized. In the case that the random seed is updated after the multiple description signal is quantized, as the initial random seed of the next sample, the random seed can be updated based on a 32-bit overflow protection function.

8. Respectively writing the quantized signals rq1_pulse and rq2_pulse into a bitstream according to the packing mode of the Opus encoding apparatus, i.e., encoding each quantized signal to generate a target bitstream corresponding to the to-be-coded signal.

9. Writing an initial value of the random seed (namely the initial random seed) into the bitstream, namely a target bitstream.

The present disclosure provides a universal compatible bitstream design method. It should be noted that the foregoing embodiment is described by taking the Opus encoding apparatus quantization mode as an example, and actually, the foregoing quantization mode may be applied to any audio encoding apparatus, video encoding apparatus, or other encoding apparatuses. In other words, any one of the existing single-description bitstream encoding apparatuses, for example, the encoding apparatuses such as Opus, EVS, USAC, H.264, or H.265, may be modified into a multiple-description bitstream encoding apparatus by using the multiple description quantization mode provided by the present disclosure. Without loss of generality, the description will be given with one most general implementation.

For example, for convenience of description, a certain sample r_Q10 in the residual signal to be quantized is taken as an example to describe the quantization process, and the other samples are quantized similarly, which will not be described again. The number of multiple description codes is assumed to be 2. In order to keep the bitstream format compatibility with a specific encoding apparatus, the encoding format and the encoding method of each multiple description bitstream are completely consistent with those of the specific encoding apparatus.

1. Obtaining multiple description residual signals r1_Q10 and r2_Q10 according to the residual signal r_Q10, i.e., determining the to-be-coded signal as a multiple description signal of the to-be-coded signal. Multiple description residual signal 1: r1_Q10=r_Q10; multiple description residual signal 2: r2_Q10=r_Q10.

2. Respectively quantizing the 2 multiple description residual signals. For example, the quantization mode only needs to ensure that the quantization mode adopted by the two multiple description residual signals is consistent with the quantization mode of the specific encoding apparatus, i.e., the set encoding apparatus, which is omitted here. It is assumed that the obtained optimal quantized signals are: rq1_pulse and rq2_pulse.

For example, this example is only described by using Opus as an example; different set encoding apparatuses may have different quantization modes, a random seed may be used or may not be used for quantization, the random seed may be used or may not be used to update a quantized signal, and the updated quantized signal is not limited and may be a candidate quantized signal or an optimal quantized signal.

For example, 2 candidate quantized signals rq11_pulse and rq12_pulse are obtained according to r1_Q10 by using a quantization mode similar to NSQ (random seed may or may not be used in the quantization mode). Two candidate quantized signals rq21_pulse and rq22_pulse are obtained according to r2_Q10 by using the same quantization mode as r1_10.

For example, 4 candidate quantized signals of r_Q10: rq_pulse1, rq_pulse2, rq_pulse3, and rq_pulse4, are obtained from the candidate quantized signals of r1_Q10 and r2_Q10. Based on the global quantization error minimization principle, the optimal quantized signal rq_pulse of r_Q10 is obtained from the 4 candidate quantized signals. The candidate quantized signals corresponding to rq_pulse are taken as the optimal quantized signals of r1_Q10 and r2_Q10. For example:

$$rq\_pulse 1 = ( srq 11 \_pulse + srq 21 \_pulse ) / 2$$

$$rq\_pulse 2 = ( srq 11 \_pulse + srq 22 \_pulse ) / 2$$

$$rq\_pulse 3 = ( srq 21 \_pulse + srq 21 \_pulse ) / 2$$

$$rq\_pulse 4 = ( srq 21 \_pulse + srq 22 \_pulse ) / 2$$

For example, srq1_pulse and srq2_pulse can be rq1_pulse and rq2_pulse, or srq1_pulse and srq2_pulse are updated rq1_pulse and rq2_pulse. The updating means may be an updating method of the set encoding apparatus. The formula for determining the candidate quantized signal combination is not limited as long as it is consistent at both the encoding and decoding ends.

For example, the error of the to-be-coded signal may be an error of the to-be-coded signal with respect to the candidate quantized signal combination, such as a quantization error of rq_pulse1 with respect to r_Q10. The quantization error before and after quantization of the multiple description signal may be a quantization error of the multiple description signal with respect to the candidate quantized signal in the corresponding candidate quantized signal set, such as a quantization error of the multiple description signal r1_Q10 with respect to the candidate quantized signal rq11_pulse in the candidate quantized signal set after quantization of the multiple description signal, a quantization error of r2_Q10 with respect to rq21_pulse. A weighted sum of the three quantization errors is determined as the error value of the candidate quantized signal combination rq_pulse1, and rq_pulse2, rq_pulse3, and rq_pulse4 are processed as above in sequence, and then a minimum value is selected from the error values.

For example, based on the global quantization error minimization principle, assuming that the quantization error of rq_pulse4 is minimum, rq_pulse4 is taken as the optimal quantized signal rq_pulse of r_Q10. Then rq21_pulse forming rq_pulse4 serves as the optimal quantized signal of r1_Q10, and rq22_pulse serves as the optimal quantized signal of r2_Q10.

3. Obtaining a true quantized signal value rq_pulse according to rq1_pulse and rq2_pulse.
rq_pulse=(srq1_pulse+srq2_pulse)/2. srq1_pulse and srq2_pulse can be rq1_pulse and rq2_pulse, or srq1_pulse and srq2_pulse are updated rq1_pulse and rq2_pulse. The updating means may be an updating method of the set encoding apparatus.

4. Writing the quantized signals rq1_pulse and rq2_pulse respectively into a bitstream, namely target bitstreams, according to a packing mode of a specific encoding apparatus.

For example, the encoding method of the present disclosure may obtain a to-be-coded signal x, and obtain up to n (n>=2) to-be-coded signals of multiple description codes x1, . . . , xn, x1=x2=xn=x, i.e., multiple description signals, from the to-be-coded signal x; the to-be-coded signals x1, . . . , xn are quantized using the encoding method of the to-be-coded signal x, to obtain quantized signals xq1, . . . , xqn, i.e., quantized signals corresponding to the multiple description signal, where the overall quantized signal xq=(xq1+ . . . , +xqn)/n (i.e., a candidate quantized signal combination corresponding to the to-be-coded signal).

For example, the quantized signals xq1, . . . , xqn are written into a bitstream, i.e., a target bitstream, according to a specific encoding method.

FIG. 3 is a schematic flowchart of a decoding method provided in some embodiments of the present disclosure. Referring to FIG. 3, the embodiment of the present disclosure is applicable to a situation of decoding a target bitstream, and the method may be executed by a decoding apparatus, and the apparatus may be implemented in a form of software and/or hardware, and optionally, implemented by an electronic device, and the electronic device may be a mobile terminal, a PC end, a server, or the like. The electronic device implementing the encoding method and the electronic device implementing the decoding method may be different electronic devices. For those parts of the present embodiment that have not been described yet, reference is made to the above embodiments, and details are not repeated herein.

For example, this step may obtain a target bitstream from a sending end, such as an electronic device that executes the methods described in FIG. 1 and FIG. 2a. The target bitstream may be generated by using the encoding method provided by the present disclosure. As shown in FIG. 3, the method includes S310 and S320.

In S310, obtaining a quantized signal from a received target bitstream. The quantized signal includes at least one of a first quantized signal or a second quantized signal. The first quantized signal is obtained by performing first quantization on a first multiple description signal. The second quantized signal is obtained by performing second quantization on a second multiple description signal. The first multiple description signal and the second multiple description signal are obtained from a same signal. For example, the same signal may be a to-be-coded signal on the encoding side.

For example, at least one quantized signal is obtained from the received target bitstream.

For example, the target bitstream includes indication information which indicates whether the target bitstream is a multiple description stream. In the case that a multiple description stream is indicated, if one quantized signal is obtained, decoding can be performed by adopting a decoding method of a set encoding apparatus. The set encoding apparatus may be a set single-bitstream encoding apparatus, such as an Opus encoding apparatus. If at least two quantized signals are obtained, the plurality of quantized signals can be combined for decoding. In the case that decoding is performed by combining a plurality of quantized signals, the mathematical operation formula for the plurality of quantized signals may be different from that used in the case that decoding is performed by the set encoding apparatus.

For example, after the target bitstream is obtained, the quantized signal may be obtained from the target bitstream. The obtaining means is not particularly limited as long as a quantized signal can be obtained, such as extracting the quantized signal from a location to which it is packed. For example, the target bitstream may be decoded based on a frame header byte of the target bitstream to obtain a quantized signal. The target bitstream is determined based on multiple description signals. One to-be-coded signal may correspond to at least one target bitstream. One to-be-coded signal may correspond to a plurality of multiple description signals. The quantized signals corresponding to a plurality of multiple description signals can be packed into at least one target bitstream.

For example, the obtained quantized signal is a quantized signal corresponding to the multiple description signal.

For example, one target bitstream may include at least one quantized signal, and this step may obtain at least one quantized signal in each target bitstream from the received at least one target bitstream.

For example, each target bitstream may include indication information indicating whether the target bitstream is a multiple description bitstream, and if so, the target bitstream may be decoded by combining a plurality of quantized signals to obtain a decoded signal. In the case that only one quantized signal is obtained, a decoded signal may be obtained by decoding only the quantized signal.

In one embodiment, in the case that the quantized signal corresponding to the multiple description signal is encoded into different bitstreams, after one target bitstream is obtained, at least one quantized signal included in the target bitstream can be obtained, indication information in the target bitstream is obtained, after the multiple description bitstream is indicated, a subsequent bitstream is continuously obtained, the quantized signals included in the subsequent bitstream are obtained, and then decoding is performed by combining the obtained quantized signals, so that a decoded signal is obtained.

In one embodiment, in the case that a quantized signal corresponding to the multiple description signal is encoded into one bitstream, after a target bitstream is obtained, at least one quantized signal included in the target bitstream may be obtained, and indication information in the target bitstream may be obtained, and after the multiple description signal is indicated, a decoded signal may be obtained based on the obtained quantized signal.

In S320, obtaining a decoded signal based on at least one of the first quantized signal or the second quantized signal. For example, obtaining a decoded signal based on the indication information and the obtained quantized signal.

In some embodiments, the target bitstream includes indication information indicating whether the target bitstream is a bitstream generated based on at least two multiple description signals. For example, a decoded signal is obtained based on at least one of the first quantized signal or the second quantized signal and the indication information.

In some embodiments, the indication information indicates that the target bitstream is a bitstream generated based on the at least two multiple description signals, and the number of the obtained quantized signals is at least two.

For example, in the case that the indication information indicates non-multiple description bitstream, it may be considered that the bitstream obtained by using the encoding method of the present disclosure is not used, and the decoding means is not limited.

For example, in the case that the indication information indicates a multiple description bitstream, the obtained quantized signal may be decoded to obtain a decoded signal.

In some embodiments, the target signal is obtained according to a combination of the first quantized signal and the second quantized signal; and a decoded signal is obtained based on the target signal.

For example, the target signal is determined from a mean or a weighted sum of the first quantized signal and the second quantized signal.

For example, in the case that at least one quantized signal is obtained, the quantized signal may be subjected to synthesis processing to obtain a decoded signal. The decoded signal may be a final decoded signal, such as decoded audio or video. The synthesis processing includes a mathematical operation such as a mean or a weighted sum.

For example, in the case that there is one quantized signal, the decoded signal may be obtained by using a set decoding method according to the quantized signal. The set decoding method may be determined based on the set decoding apparatus corresponding to the set encoding apparatus. The set decoding method includes a set updating method, which may be used to obtain an updated quantized signal. The quantized signal updating means is the same as the means for updating the quantized signal on the encoding apparatus side. After the quantized signal is updated by adopting the set updating method, the quantized signal can be subjected to a mathematical operation to obtain a decoded signal.

In one embodiment, in the case that there are at least two quantized signals, a mean of the quantized signals is determined as the target signal. A decoded signal is obtained based on the target signal.

In one embodiment, in the case that there are at least two quantized signals, the quantized signals or the updated quantized signals may be subjected to a mathematical operation to obtain the target signal, for example, a set updating method is used to obtain the updated quantized signals, and a mean of the quantized signals is determined as the target signal. A decoded signal is then obtained based on the target signal.

For example, the target signal may be a quantized signal determined by combining one or more target bitstreams. The determination means of the target signal is not limited herein. For example, a mean of at least two quantized signals (or updated quantized signals) may be determined as the target signal, and a weighted result of at least two quantized signals (or updated quantized signals) may be determined as the target signal, for example, at least two quantized signals (or updated quantized signals) may be respectively multiplied by corresponding coefficients (a sum of the coefficients corresponding to each quantized signal may be 1), and a sum of all the products may be determined as the target signal. The means for determining the target signal shall be ensured to be the same as the technical means for determining the candidate quantized signal combination at the encoding end.

In the embodiments of the present disclosure, after the target bitstream of the to-be-coded signal is received, the decoding signal can be obtained based on the quantized signal included in each target bitstream, each target bitstream can be decoded, and the more the target bitstreams are received, the higher the decoding quality is, improving the packet loss resistance. In addition, the target bitstream can be obtained with reference to the encoding of the set encoding apparatus, improving the use scene of the target bitstream, and enabling the encoding apparatus to be interworked with the set encoding apparatus. In the case that the encoding apparatus and the set encoding apparatus are interworked, the adopted decoding method may be indicated based on the indication information included in the target bitstream. In the case that the indication information indicates that the target bitstream is a single description bitstream, decoding can be performed by adopting a decoding method of a set decoding apparatus corresponding to the set encoding apparatus; in the case that the indication information indicates that the target bitstream is a multiple description bitstream, the decoding apparatus can decode in combination with a plurality of quantized signals; in the case that only one quantized signal is obtained, the quantized signal can be directly decoded, the quantized signal can be updated during decoding, a decoded signal is obtained based on the updated quantized signal, and the decoding method for the quantized signal can be the same as the decoding method of the set decoding apparatus corresponding to the set encoding apparatus.

In some embodiments, a random seed corresponding to the quantized signal is obtained from the target bitstream to obtain the target signal.

In one embodiment, the decoding method further includes: obtaining a random seed corresponding to the quantized signal from the received target bitstream.

For example, the present embodiment may also obtain a random seed from the target bitstream. The means for obtaining the random seed corresponding to the multiple description signal is not limited, and the random seed may be obtained from a position where the random seed is located.

For example, after the random seed is obtained, the target bitstream may be decoded based on the obtained random seed to obtain a decoded signal.

For example, the random seed corresponding to the quantized signal is an initial random seed.

In some embodiments, updating a first random seed corresponding to the first quantized signal to obtain an updated first random seed, and updating a second random seed corresponding to the second quantized signal to obtain an updated second random seed; updating the first quantized signal based on the updated first random seed to obtain an updated first quantized signal, and updating the second quantized signal based on the updated second random seed to obtain an updated second quantized signal; determining a target signal according to a mean or weighted sum of the updated first quantized signal and the updated second quantized signal; and obtaining a decoded signal based on the target signal.

For example, the first random seed corresponding to the first quantized signal includes an initial first random seed, and the second random seed corresponding to the second quantized signal includes an initial second random seed. For example, the first random seed corresponding to the first quantized signal may be an initial first random seed, and the second random seed corresponding to the second quantized signal may be an initial second random seed.

In one embodiment, the obtaining a decoded signal based on the indication information and the obtained quantized signal, includes: updating a random seed corresponding to each quantized signal; in the case that the indication information indicates that the target bitstream is a multiple description bitstream and the number of the obtained quantized signals is at least two, updating the corresponding quantized signals based on the updated random seed of each quantized signal to obtain updated quantized signals; determining a mean of each updated quantized signal as a target signal; and obtaining the decoded signal based on the target signal.

For example, in decoding, since the initial random seed corresponding to the quantized signal may be obtained, after the initial random seed is obtained, the random seed corresponding to each quantized signal may be updated based on a random seed updating method of the set encoding apparatus.

For example, if the updated random seed corresponding to the quantized signal is obtained, the decoding end may not perform the operation of updating the random seed corresponding to the quantized signal.

For example, after updating the random seed, the quantized signals may be updated, such as inverted, based on the random seed of each quantized signal. For example, whether to invert the quantized signal may be determined based on a magnitude of the random seed. The quantized signal may not be inverted in the case that the random seed is greater than zero. The quantized signal may be inverted in the case that the random seed is not greater than zero.

For example, after obtaining the updated quantized signals, the mean of the updated quantized signals may be determined as the target signal. After obtaining the target signal, a decoded signal may be obtained based on the target signal, and specific technical means for obtaining the decoded signal based on the target signal is not limited herein.

FIG. 4 is a schematic flowchart of another decoding method provided in some embodiments of the present disclosure, and the embodiment refines the step of obtaining a decoded signal, and with reference to FIG. 4, the method includes S410 to S430.

For example, the target bitstream is generated by using the encoding method provided by the present disclosure.

In S410, obtaining at least one quantized signal from a received target bitstream.

For example, the target bitstream is determined based on a multiple description signal. In the case that the target bitstream is obtained based on encoding of the multiple description signal, the target bitstream can be encoded based on the encoding method provided in the embodiment of the present disclosure.

In S420, in the case that the indication information indicates that the target bitstream is a multiple description bitstream, and in the case that the number of the obtained quantized signals is at least two, combining the quantized signals to obtain a target signal.

For example, the quantized signals may be combined in the step to obtain a target signal. The combination is not limited, and the combination at the encoding and decoding ends may be the same or different. For example, in the case that combining the candidate quantized signals in the candidate quantized signal set at the encoding end to obtain the candidate quantized signal combination, the used combination is the same.

In one embodiment, after the quantized signals are obtained, the mean of the quantized signals is directly determined as the target signal.

In one embodiment, after the quantized signals are obtained, a weighted sum of the quantized signals is determined as the target signal. A sum of weight coefficients of each quantized signal may be 1.

In some embodiments, this step may further update the quantized signals by using the set update method, to determine the target signal based on the updated quantized signals, where the means for updating the quantized signals by the set decoding method is not limited, and may refer to the decoding method of the set decoding apparatus corresponding to the set encoding apparatus.

For example, after updating the quantized signal, the mean of the updated quantized signals may be determined as the target signal.

In S430, obtaining a decoded signal based on the target signal.

For example, in the embodiment of the present disclosure, the target signal of the decoding signal may be obtained by synthesizing quantized signals included in a plurality of target bitstreams, improving the decoding quality and packet loss resistance. In addition, the target bitstream can be obtained based on the encoding mode of the set encoding apparatus, improving the application scene of the target bitstream, so that not only a special decoding apparatus but also the set decoding apparatus can be used for decoding. The special decoding apparatus can be regarded as a decoding apparatus specially used for decoding the target bitstream generated by a novel encoding apparatus. The novel encoding apparatus may be regarded as the encoding apparatus that performs the encoding method of the present disclosure.

The decoding method provided by the present disclosure is exemplarily explained below, and the decoding method for the compatible Opus encoding apparatus traverses samples to perform the decoding operation as follows.

For example, the first case is that the decoding apparatus receives 2 multiple description bitstreams, i.e. target bitstreams; the second case is that the decoding apparatus receives only 1 multiple description bitstream.

For example, in the first case, quantized signals (i.e., quantized signals corresponding to the multiple description signals) rq1_pulse and rq2_pulse, and random seed initial values (i.e., random seeds corresponding to the multiple description signals) seed1 and seed2, are obtained from a multiple description bitstream, where seed1 is a random seed initial value corresponding to a quantized signal in a multiple description bitstream 1, and seed2 is a random seed initial value corresponding to a quantized signal in a multiple description bitstream 2.

1. Updating values of the random seeds seed1 and seed2, namely, updating the random seeds corresponding to each quantized signal, i.e., the random seeds corresponding to the multiple description signals corresponding to the quantized signals, by adopting a random seed updating method of the set encoding apparatus;

$$seed 1 = rand ( seed 1 ) ;$$

$$seed 2 = rand ( seed 2 ) ;$$

$$rand ( x ) = overflow 32 ( 907633515 + x * 196314165 ) .$$

2. Obtaining a quantized signal rq_pulse according to the random seeds seed1, seed2, and the quantized signals rq1_pulse and rq2_pulse, i.e., in the case that the indication information indicates that the target bitstream is a multiple description bitstream, and in the case that the number of the obtained quantized signals is at least two, updating the corresponding quantized signals based on the updated random seeds of each quantized signal, so as to obtain updated quantized signals.

For example, if seed1 is smaller than 0-rq1_pulse is determined as the updated quantized signal of the multiple description signal 1; otherwise, rq1_pulse is determined as the updated quantized signal of the multiple description signal 1.

For example, if seed2 is smaller than 0-rq2_pulse is determined as the updated quantized signal of the multiple description signal 2; otherwise, rq2_pulse is determined as the updated quantized signal of the multiple description signal 2.

For example, in the case that the number of the target bitstreams is at least two, the corresponding quantized signal is inverted based on the updated random seeds of each quantized signal to obtain the updated quantized signal; rq_pulse=(srq1_pulse+srq2_pulse)/2, that is, a mean of each updated quantized signal is determined as the target signal.

3. Respectively updating the corresponding random seed (seed values). seed 1=overflow32 (seed1+rq1_pulse); seed 2=overflow32 (seed2+rq2_pulse).

For example, for the decoding method of the other samples, the above decoding process is repeated on the basis of the updated seed of the previous sample.

For example, in the second case, the decoding apparatus receives only 1 multiple description bitstream (the Opus decoding apparatus decodes a single multiple description bitstream): considering that the decoding apparatus may receive the multiple description bitstream 1 or the multiple description bitstream 2, in order to avoid loss of generality, it is assumed here that what is obtained from a certain multiple description bitstream is the quantized signal rq1_pulse, and the random seed initial value seed1. Because the format and the pulse quantization mode of the 2 multiple description bitstreams are completely the same, the decoding method of the multiple description bitstreams is completely consistent. And the decoding method is completely consistent with the Opus decoding apparatus.

For example, the decoding process is as follows: updating the value of the random seed 1: seed 1=rand (seed 1); rand (x)=overflow32 (907633515+x*196314165).

For example, the final quantized signal rq_pulse is obtained from the random seed (seed) and the quantized signal rq1_pulse: if seed1 is less than 0, −rq1_pulse is taken as the final quantized signal; otherwise, rq1_pulse is taken as the final quantized signal.

For example, update the random seed1 value: seed 1=overflow32 (seed1+rq1_pulse).

For example, for a general compatible bitstream, there are two decoding methods: the first is that the decoding apparatus receives 2 multiple description bitstreams; the second is that the decoding apparatus receives only 1 multiple description bitstream.

For example, the first is that the decoding apparatus receives 2 multiple description bitstreams: obtaining quantized signals rq1_pulse and rq2_pulse from the multiple description bitstreams (namely target bitstreams), i.e., obtaining at least one quantized signal from the received target bitstreams.

For example, a quantized signal rq_pulse is obtained according to the quantized signals rq1_pulse and rq2_pulse, that is, in the case that the number of the target bitstreams is at least two, a target signal is obtained based on the corresponding at least two quantized signals: rq_pulse=(srq1_pulse+srq2_pulse)/2. The srq1_pulse and srq2_pulse may be quantized signals updated for rq1_pulse and rq2_pulse by adopting the set updating method.

For example, it should be noted that, rq1_pulse and rq2_pulse may not be updated, and rq_pulse=(rq1_pulse+rq2_pulse)/2.

For example, the second is that the decoding apparatus receives only 1 multiple description bitstream (the Opus decoding apparatus decodes a single multiple description bitstream): considering that the decoding apparatus may receive the multiple description bitstream 1 or the multiple description bitstream 2, in order to avoid loss of generality, it is assumed that a quantized signal (i.e., a quantized signal corresponding to the multiple description signal) obtained from a certain multiple description bitstream is rq1_pulse, and therefore, a decoding method of a single multiple description bitstream is completely consistent with a decoding method of a specific encoding apparatus.

For example, the decoding process is as follows:
1. Obtaining a quantized signal rq1_pulse from the bitstream;
2. Obtaining a final quantized signal rq_pulse, i.e. the target signal, from the quantized signal rq1_pulse. For example, the quantized signal rq1_pulse is taken as the final quantized signal rq_pulse.

For example, the decoding method of the present disclosure may receive at least one multiple description bitstream, i.e., the target bitstream. Obtaining m (m>=1, m<=n) multiple description bitstreams from n (n>=2) multiple description bitstreams, and obtaining quantized signals xq1, . . . xqm, namely quantized signals corresponding to the multiple description signals, from the m multiple description bitstreams; obtaining a reconstructed signal xq=(xq1+ . . . +xqm)/m, namely a target signal, according to the quantized signals xq1, . . . xqm; obtaining a decoded voice, i.e. a decoded signal, from the reconstructed signal.

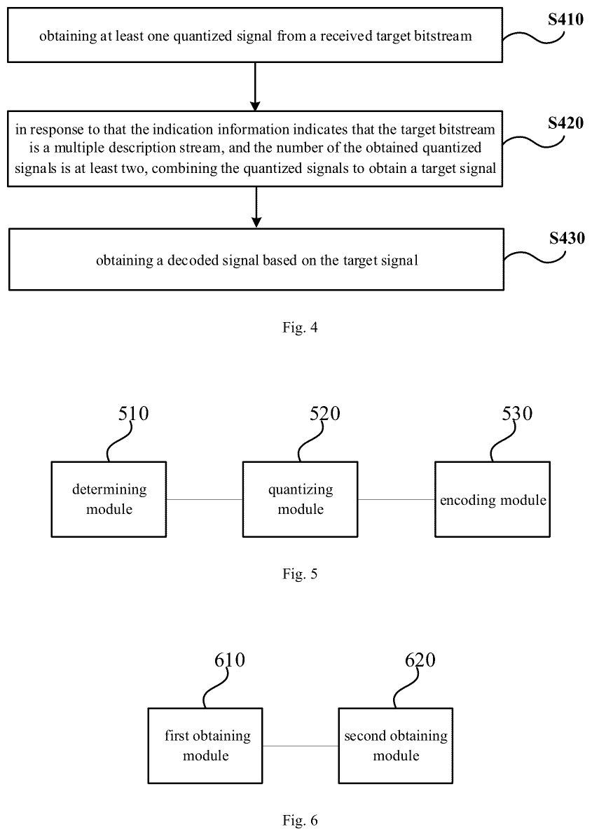

FIG. 5 is a schematic structural diagram of an encoding apparatus provided in some embodiments of the present disclosure, and as shown in FIG. 5, the apparatus includes: a determining module 510, configured to determine a to-be-coded signal as a multiple description signal of the to-be-coded signal, the number of the multiple description signals is at least two; a quantizing module 520, configured to quantize each of the multiple description signals respectively to obtain a candidate quantized signal set; obtain a quantized signal corresponding to each multiple description signal according to each candidate quantized signal set; and an encoding module 530, configured to encode each quantized signal to generate a target bitstream of the to-be-coded signal, where the target bitstream includes indication information which indicates whether the target bitstream is a multiple description bitstream.

In some embodiments, the encoding apparatus includes: a determining module 510 configured to, obtain at least two multiple description signals according to a to-be-coded signal, the at least two multiple description signals including a first multiple description signal and a second multiple description signal; a quantizing module 520 configured to, perform first quantization on the first multiple description signal to obtain a first candidate quantized signal set, and perform second quantization on the second multiple description signal to obtain a second candidate quantized signal set; obtain a first quantized signal corresponding to the first multiple description signal and a second quantized signal corresponding to the second multiple description signal according to the first candidate quantized signal set and the second candidate quantized signal set; and an encoding module 530 configured to, encode the first quantized signal and the second quantized signal to generate a target bitstream corresponding to the to-be-coded signal.

In some embodiments, the target bitstream includes indication information indicating whether the target bitstream is a bitstream generated based on the at least two multiple description signals.

In some embodiments, the quantizing module 520 performs the first quantization on the first multiple description signal according to a first random seed corresponding to the first multiple description signal and performs the second quantization on the second multiple description signal according to a second random seed corresponding to the second multiple description signal.

In some embodiments, the first random seed includes an initial first random seed and an updated first random seed. The quantizing module 520 obtains the initial first random seed, updates the initial first random seed, and obtains an updated first random seed; updates the first multiple description signal based on the updated first random seed to obtain an updated first multiple description signal; and performs the first quantization on the updated first multiple description signal to obtain a first candidate quantized signal set.

In some embodiments, the second random seed includes an initial second random seed and an updated second random seed. The quantizing module 520 obtains the initial second random seed, and updates the initial second random seed to obtain an updated second random seed; updates the second multiple description signal based on the updated second random seed to obtain an updated second multiple description signal; and performs the second quantization on the updated second multiple description signal to obtain a second candidate quantized signal set.

In some embodiments, the quantizing module 520 obtains a plurality of candidate quantized signal combinations of the to-be-coded signal according to the first candidate quantized signal set and the second candidate quantized signal set, each candidate quantized signal combination including a plurality of candidate quantized signals that are obtained according to a first candidate quantized signal in the first candidate quantized signal set and a second candidate quantized signal in the second candidate quantized signal set, and selects one candidate quantized signal combination from the plurality of candidate quantized signal combinations as a target quantized signal combination of the to-be-coded signal; and determines a first quantized signal according to the first candidate quantized signal corresponding to the target quantized signal combination, and determines a second quantized signal according to the second candidate quantized signal corresponding to the target quantized signal combination.

In some embodiments, the quantizing module 520 selects a candidate quantized signal combination with a minimum quantization error from the plurality of the candidate quantized signal combinations as the target quantized signal combination.

In some embodiments, the target bitstream includes the first random seed and the second random seed.

In some embodiments, the target bitstream includes an initial first random seed and an initial second random seed.

According to the technical solution provided by the embodiments of the present disclosure, the to-be-coded signal is directly determined to be at least two multiple description signals of the to-be-coded signal, so that encoding of each multiple description signal is encoding of the to-be-coded signal, which improves the packet loss resistance of the encoding apparatus. In the case that the target bitstream is obtained by the encoding, the bitstream format of the target bitstream can be the same as the bitstream format of the set encoding apparatus, enabling the encoding apparatus of the present disclosure to be compatible with the set encoding apparatus. The encoding apparatus and the decoding apparatus in the related arts exist correspondingly, so that it is only needed to determine mutually the corresponding encoding and decoding methods, without considering compatibility. In the present disclosure, indication information is introduced since compatibility is considered, and in the case that the encoding apparatus of the present disclosure is interworked with the set encoding apparatus, the indication information included in the target bitstream can be used for indicating whether the target bitstream is a multiple description stream, so as to indicate the decoding method of the encoding apparatus, ensuring the compatibility of the encoding apparatus of the present disclosure with the set encoding apparatus.

In one embodiment, the quantizing module 520 is configured to: obtain an initial random seed corresponding to each multiple description signal, and update the initial random seed of each multiple description signal; update the corresponding multiple description signal based on the updated random seed; and respectively quantize each inverted multiple description signal to obtain a candidate quantized signal set.

In one embodiment, the quantizing module 520 is configured to: obtain a plurality of candidate quantized signal combinations of the to-be-coded signal according to each candidate quantized signal set, the candidate quantized signals combinations being combinations of candidate quantized signals in candidate quantized signal sets corresponding to different multiple description signals; select one candidate quantized signal from each candidate quantized signal combination according to a set selection method, as a target quantized signal of the to-be-coded signal, where the set selection method includes taking a candidate quantized signal combination with a minimum quantization error in the candidate quantized signal combinations as the target quantized signal of the to-be-coded signal; and determine the candidate quantized signals in the candidate quantized signal set corresponding to the target quantized signal as the quantized signals corresponding to each multiple description signal.

In some embodiments, the target bitstream includes a random seed corresponding to the quantized signal.

In one embodiment, the random seed corresponding to the quantized signal is an initial random seed.

The encoding apparatus provided in the embodiment of the present disclosure can execute the encoding method provided by any embodiment of the present disclosure, and has corresponding functional modules and beneficial effects of the executed method.

It should be noted that, the units and modules included in the above apparatus are merely divided according to functional logic, but are not limited to the above division as long as the corresponding functions can be implemented; in addition, the names of the functional units are only for convenience of distinguishing from each other, and are not used for limiting the protection scope of the embodiments of the present disclosure.

FIG. 6 is a schematic structural diagram of a decoding apparatus provided in some embodiments of the present disclosure, and as shown in FIG. 6, the apparatus includes: a first obtaining module 610, configured to obtain at least one quantized signal from a received target bitstream, where the target bitstream includes indication information which indicates whether the target bitstream is a multiple description bitstream; and a second obtaining module 620, configured to obtain a decoded signal based on the indication information and the obtained quantized signal.

In some embodiments, the decoding apparatus includes: a first obtaining module 610 configured to, obtain a quantized signal from a received target bitstream, where the quantized signal includes at least one of a first quantized signal or a second quantized signal, the first quantized signal is obtained by performing first quantization on a first multiple description signal, the second quantized signal is obtained by performing second quantization on a second multiple description signal, and the first multiple description signal and the second multiple description signal are obtained from a same signal; and a second obtaining module 620 configured to, obtain a decoded signal based on at least one of the first quantized signal or the second quantized signal.

In some embodiments, the target bitstream includes indication information which indicates whether the target bitstream is a bitstream generated based on at least two multiple description signals. The second obtaining module 620 obtains the decoded signal based on the indication information and at least one of the first quantized signal or the second quantized signal.

In some embodiments, the indication information indicates that the target bitstream is a bitstream generated based on at least two multiple description signals, and the number of the obtained quantized signals is at least two.

In some embodiments, the second obtaining module 620 obtains the target signal according to a combination of the first quantized signal and the second quantized signal, and obtains the decoded signal based on the target signal.

In some embodiments, the second obtaining module 620 determines the target signal based on a mean or a weighted sum of the first quantized signal and the second quantized signal.

In some embodiments, the second obtaining module 620 obtains a random seed corresponding to the quantized signal from the target bitstream, so as to obtain the target signal.

In some embodiments, the second obtaining module 620 updates the first random seed corresponding to the first quantized signal to obtain an updated first random seed, updates the second random seed corresponding to the second quantized signal to obtain an updated second random seed, updates the first quantized signal based on the updated first random seed to obtain an updated first quantized signal, updates the second quantized signal based on the updated second random seed to obtain an updated second quantized signal, and determines the target signal according to a mean or a weighted sum of the updated first quantized signal and the updated second quantized signal; and obtain the decoded signal based on the target signal.

In some embodiments, the first random seed corresponding to the first quantized signal includes an initial first random seed, and the second random seed corresponding to the second quantized signal includes an initial second random seed.

According to the technical solution provided in the embodiment of the present disclosure, after the target bitstream of the to-be-coded signal is received, the decoding signal can be obtained based on the quantized signal included in each target bitstream, each target bitstream can be decoded, and the more the target bitstreams are received, the higher the decoding quality is, improving the packet loss resistance. In addition, the target bitstream can be obtained with reference to the encoding of the set encoding apparatus, improving the use scene of the target bitstream, and enabling the encoding apparatus to be interworked with the set encoding apparatus. In the case that the encoding apparatus and the set encoding apparatus are interworked, the adopted decoding method may be indicated based on the indication information included in the target bitstream. In the case that the indication information indicates that the target bitstream is a single description bitstream, decoding can be performed by adopting a decoding method of a set decoding apparatus corresponding to the set encoding apparatus; in the case that the indication information indicates that the target bitstream is a multiple description bitstream, the decoding apparatus can decode in combination with a plurality of quantized signals; in the case that only one quantized signal is obtained, the quantized signal can be directly decoded, the quantized signal can be updated during decoding, a decoded signal is obtained based on the updated quantized signal, and the decoding method for the quantized signal can be the same as the decoding method of the set decoding apparatus corresponding to the set encoding apparatus.

In one embodiment, the second obtaining module 620 includes: a combining unit configured to combine the quantized signals to obtain a target signal, in the case that the indication information indicates that the target bitstream is a multiple description bitstream and the number of the obtained quantized signals is at least two; and an obtaining unit configured to obtain the decoded signal based on the target signal.

In one embodiment, the combining unit is configured to: determine a mean or a weighted sum of the quantized signals as the target signal.

In one embodiment, the apparatus further includes a third obtaining module configured to: obtain a random seed corresponding to the quantized signal from the received target bitstream.

In one embodiment, the second obtaining module 620 is configured to: update the random seed corresponding to each quantized signal; in the case that the indication information indicates that the target bitstream is a multiple description bitstream and the number of the obtained quantized signals is at least two, update the corresponding quantized signals based on the updated random seed of each quantized signal to obtain updated quantized signals; determine a mean of each updated quantized signal as a target signal; and obtain the decoded signal based on the target signal.

The decoding apparatus provided in the embodiment of the present disclosure can execute the decoding method provided by any embodiment of the present disclosure, and has corresponding functional modules and beneficial effects of the executed method.

It should be noted that, the units and modules included in the above apparatus are merely divided according to functional logic, but are not limited to the above division as long as the corresponding functions can be implemented; in addition, the names of the functional units are only for convenience of distinguishing from each other, and are not used for limiting the protection scope of the embodiments of the present disclosure.

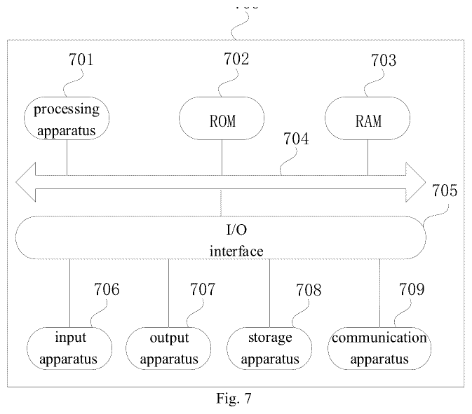

FIG. 7 is a schematic structural diagram of an electronic device provided by some embodiments of the present disclosure. Referring now to FIG. 7, shown is a schematic block diagram of an electronic device (e.g., a terminal device or server in FIG. 7) 700 suitable for implementing the embodiments of the present disclosure.

The electronic device 700 includes: one or more processing apparatus 701; a storage apparatus 708 for storing one or more programs which, when executed by the one or more processing apparatus 701, cause the one or more processing apparatus 701 to implement the encoding method and/or the decoding method according to the embodiments of the present disclosure.

The terminal device in the embodiments of the present disclosure may include, but is not limited to, a mobile terminal such as a mobile phone, a notebook computer, a digital broadcast receiver, a PDA (personal digital assistant), a PAD (tablet computer), a PMP (portable multimedia player), a vehicle terminal (e.g., a vehicle navigation terminal), and the like, and a fixed terminal such as a digital TV, a desktop computer, and the like. The electronic device shown in FIG. 7 is only an example, and should not bring any limitation to the functions and the scope of use of the embodiments of the present disclosure.

As shown in FIG. 7, the electronic device 700 may include a processing apparatus (e.g., central processing unit, graphics processor, etc.) 701 that may perform various appropriate actions and processes in accordance with a program stored in a Read Only Memory (ROM) 702 or a program loaded from a storage apparatus 708 into a Random Access Memory (RAM) 703. In the RAM 703, various programs and data necessary for the operation of the electronic device 700 are also stored. The processing apparatus 701, the ROM 702, and the RAM 703 are connected to each other via a bus 704. An input/output (I/O) interface 705 is also connected to the bus 704.

Generally, the following apparatus may be connected to the I/O interface 705: input apparatus 706 including, for example, a touch screen, touch pad, keyboard, mouse, camera, microphone, accelerometer, gyroscope, or the like; an output apparatus 707 including, for example, a Liquid Crystal Display (LCD), a speaker, a vibrator, and the like; a storage apparatus 708, including, for example, magnetic tape, hard disk, etc.; and a communication apparatus 709. The communication apparatus 709 may allow the electronic device 700 to communicate with other devices, wireless or wired, to exchange data. While FIG. 7 illustrates the electronic device 700 having various apparatus, it is to be understood that not all illustrated apparatus are required to be implemented or provided. More or fewer means may be alternatively implemented or provided.

In particular, the processes described above with reference to the flow diagrams may be implemented as computer software programs, according to the embodiments of the present disclosure. For example, the embodiments of the present disclosure include a computer program product including a computer program carried on a non-transitory computer readable medium, the computer program including program code for performing the method illustrated by the flowchart. In such an embodiment, the computer program may be downloaded and installed from a network via the communication apparatus 709, or may be installed from the storage apparatus 708, or may be installed from the ROM 702. The computer program, when executed by the processing apparatus 701, performs the above functions defined in the methods of the embodiments of the present disclosure.

The names of messages or information exchanged between apparatus in the embodiments of the present disclosure are for illustrative purposes only, and are not intended to limit the scope of the messages or information.

The electronic device provided by the embodiment of the present disclosure and the encoding method and/or decoding method provided by the above embodiments belong to the same inventive concept, and technical details that are not described in detail in the embodiment can be referred to the above embodiments, and the embodiment has the same beneficial effects as the above embodiments.

Some embodiments of the present disclosure provide a non-transitory computer storage medium having thereon stored a computer program which, when executed by a processor, implements an encoding method and/or a decoding method provided by the above embodiments.

It should be noted that the computer readable medium of the present disclosure may be a computer readable signal medium or a computer readable storage medium or any combination of the two.

The computer storage medium may be a storage medium for computer-executable instructions which, when executed by a computer processor, performs the method as provided by the present disclosure.

The computer readable storage medium may be, for example, but is not limited to: an electronic, magnetic, optical, electromagnetic, infrared, or semiconductor system, apparatus, or device, or any combination of the foregoing. More specific examples of the computer readable storage medium may include, but are not limited to: an electrical connection having one or more wires, a portable computer diskette, a hard disk, a Random Access Memory (RAM), a read-only memory (ROM), an erasable programmable read-only memory (EPROM or flash memory), an optical fiber, a portable compact disc read-only memory (CD-ROM), an optical storage device, a magnetic storage device, or any suitable combination of the foregoing. In the present disclosure, the computer readable storage medium may be any tangible medium that can include, or store a program for use by or in connection with an instruction execution system, apparatus, or device. In contrast, in the present disclosure, the computer readable signal medium may include a propagated data signal with computer readable program code embodied therein, for example, in baseband or as part of a carrier wave. Such a propagated data signal may take any of a variety of forms, including, but not limited to, electro-magnetic, optical, or any suitable combination thereof. The computer readable signal medium may be any computer readable medium other than the computer readable storage medium and can communicate, propagate, or transport a program for use by or in connection with an instruction execution system, apparatus, or device. Program code embodied on a computer readable medium may be transmitted using any appropriate medium, including but not limited to: electrical wires, optical cables, RF (radio frequency), etc., or any suitable combination of the foregoing.

In some embodiments, the clients, servers may communicate using any currently known or future developed network protocol, such as HTTP (HyperText Transfer Protocol), and may be interconnected with any form or medium of digital data communication (e.g., a communication network). Examples of communication networks include a local area network (“LAN”), a wide area network (“WAN”), an internet (e.g., the Internet), and a peer-to-peer network (e.g., ad hoc peer-to-peer network), as well as any currently known or future developed network.

The computer readable medium may be embodied in the above electronic device; or may be separate and not assembled into the electronic device.

The computer readable medium carries one or more programs which, when executed by the electronic device, cause the electronic device to: determine a to-be-coded signal as a multiple description signal of the to-be-coded signal, where the number of the multiple description signal is at least two; respectively quantize each multiple description signal to obtain a candidate quantized signal set; obtain a quantized signal corresponding to each multiple description signal according to each candidate quantized signal set; and encode each quantized signal to generate a target bitstream of the to-be-coded signal, where the target bitstream includes indication information which indicates whether the target bitstream is a multiple description bitstream.

Alternatively, the computer readable medium carries one or more programs which, when executed by the electronic device, cause the electronic device to: obtain at least one quantized signal from a received target bitstream, where the target bitstream includes indication information which indicates whether the target bitstream is a multiple description bitstream; and obtain a decoded signal based on the indication information and the obtained quantized signal.

Computer program code for carrying out operations of the present disclosure may be written in one or more programming languages or any combination thereof, including but not limited to an object oriented programming language, such as Java, Smalltalk, C++, also including conventional procedural programming languages, such as “C” language or similar programming languages. The program code may be executed entirely on the user's computer, partly on the user's computer, as a stand-alone software package, partly on the user's computer and partly on a remote computer, or entirely on the remote computer or server. In the scenario related to remote computer, the remote computer may be connected to the user's computer through any type of network, including a Local Area Network (LAN) or a Wide Area Network (WAN), or may be connected to an external computer (for example, through the Internet using an Internet service provider).

The flow and block diagrams in the figures illustrate the architecture, functionality, and operation of possible implementations of systems, methods and computer program products according to various embodiments of the present disclosure. In this regard, each block in the flow or block diagrams may represent a module, segment, or portion of code, which includes one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in a reverse order, depending upon the functionality involved. It will also be noted that each block of the block diagrams and/or flow diagrams, and combinations of blocks in the block diagrams and/or flow diagrams, can be implemented by special purpose hardware-based systems that perform the specified functions or actions, or combinations of special purpose hardware and computer instructions.

The modules or units described in the embodiments of the present disclosure may be implemented by software or hardware. The name of a module or unit does not in some cases constitute a limitation of the unit itself, for example, the obtaining module may also be described as a “multiple description signal obtaining module”.

The functions described herein above may be performed, at least in part, by one or more hardware logic components. For example, without limitation, exemplary types of hardware logic components that may be used include: field Programmable Gate Array (FPGA), Application Specific Integrated Circuit (ASIC), Application Specific Standard Product (ASSP), system on a chip (SOC), Complex Programmable Logic Device (CPLD), and the like.

In the context of this disclosure, the machine-readable medium may be a tangible medium that can include, or store a program for use by or in connection with an instruction execution system, apparatus, or device. The machine-readable medium may be a machine-readable signal medium or a machine-readable storage medium. The machine-readable medium may include, but is not limited to, an electronic, magnetic, optical, electromagnetic, infrared, or semiconductor system, apparatus, or device, or any suitable combination of the foregoing. More specific examples of the machine-readable storage medium would include an electrical connection based on one or more wires, a portable computer diskette, a hard disk, a Random Access Memory (RAM), a read-only memory (ROM), an erasable programmable read-only memory (EPROM or flash memory), an optical fiber, a portable compact disc read-only memory (CD-ROM), an optical storage device, a magnetic storage device, or any suitable combination of the foregoing.

The foregoing description is merely illustration of the preferred embodiments of the present disclosure and the technical principles employed. It should be appreciated by those skilled in the art that the disclosure scope involved in the present disclosure is not limited to the technical solutions formed by specific combinations of the above technical features, but also encompasses other technical solutions formed by arbitrary combinations of the above technical features or equivalent features thereof without departing from the above disclosed concepts, for example, a technical solution formed by performing mutual replacement between the above features and technical features having similar functions to those disclosed (but not limited to) in the present disclosure.

Furthermore, while operations are depicted in a specific order, this should not be understood as requiring that these operations be performed in the specific order shown or in a sequential order. Under certain circumstances, multitasking and parallel processing may be advantageous. Similarly, while several specific implementation details are included in the above discussion, these should not be construed as limitations on the scope of the present disclosure. Certain features that are described in the context of separate embodiments may also be implemented in combination in a single embodiment. Conversely, various features that are described in the context of a single embodiment may also be implemented in multiple embodiments separately or in any suitable sub-combination.

Although the subject matter has been described in language specific to structural features and/or method logical actions, it should be understood that the subject matter defined in the attached claims is not necessarily limited to the specific features or actions described above. Rather, the specific features and actions described above are only example forms of implementing the claims.

What is claimed is:

1. An encoding method, comprising:
obtaining at least two multiple description signals according to a to-be-coded signal, the at least two multiple description signals comprising a first multiple description signal and a second multiple description signal;
performing first quantization on the first multiple description signal to obtain a first candidate quantized signal set, and performing second quantization on the second multiple description signal to obtain a second candidate quantized signal set;
obtaining a first quantized signal corresponding to the first multiple description signal and a second quantized signal corresponding to the second multiple description signal according to the first candidate quantized signal set and the second candidate quantized signal set; and
encoding the first quantized signal and the second quantized signal to generate a target bitstream corresponding to the to-be-coded signal.

2. The encoding method according to claim 1, wherein the target bitstream comprises indication information which indicates whether the target bitstream is a bitstream generated based on the at least two multiple description signals.

3. The encoding method according to claim 1, wherein the performing the first quantization on the first multiple description signal to obtain the first candidate quantized signal set, and performing the second quantization on the second multiple description signal to obtain the second candidate quantized signal set, comprises:
performing the first quantization on the first multiple description signal according to a first random seed corresponding to the first multiple description signal, and performing the second quantization on the second multiple description signal according to a second random seed corresponding to the second multiple description signal.

4. The encoding method according to claim 3, wherein the first random seed comprises an initial first random seed and an updated first random seed, and
the performing the first quantization on the first multiple description signal according to the first random seed corresponding to the first multiple description signal, comprises:
obtaining the initial first random seed;
updating the initial first random seed to obtain the updated first random seed;
updating the first multiple description signal based on the updated first random seed, to obtain an updated first multiple description signal; and
performing the first quantization on the updated first multiple description signal to obtain the first candidate quantized signal set.

5. The encoding method according to claim 3, wherein the second random seed comprises an initial second random seed and an updated second random seed, and
the performing the second quantization on the second multiple description signal according to the second random seed corresponding to the second multiple description signal, comprises:
obtaining the initial second random seed;
updating the initial second random seed to obtain the updated second random seed;
updating the second multiple description signal based on the updated second random seed to obtain an updated second multiple description signal; and
performing the second quantization on the updated second multiple description signal to obtain the second candidate quantized signal set.

6. The encoding method according to claim 1, wherein the obtaining the first quantized signal corresponding to the first multiple description signal and the second quantized signal corresponding to the second multiple description signal according to the first candidate quantized signal set and the second candidate quantized signal set, comprises:
obtaining a plurality of candidate quantized signal combinations of the to-be-coded signal according to the first candidate quantized signal set and the second candidate quantized signal set, wherein a plurality of candidate quantized signals comprised in each candidate quantized signal combination of the plurality of candidate quantized signal combinations are obtained according to a first candidate quantized signal in the first candidate quantized signal set and a second candidate quantized signal in the second candidate quantized signal set;
selecting one candidate quantized signal combination from the plurality of candidate quantized signal combinations as a target quantized signal combination of the to-be-coded signal; and
determining the first quantized signal according to a first candidate quantized signal corresponding to the target quantized signal combination, and determining the second quantized signal according to a second candidate quantized signal corresponding to the target quantized signal combination.

7. The encoding method according to claim 6, wherein the selecting the one candidate quantized signal combination from the plurality of candidate quantized signal combinations as the target quantized signal combination of the to-be-coded signal, comprises:
selecting a candidate quantized signal combination with a minimum quantization error in the plurality of candidate quantized signal combinations, as the target quantized signal combination.

8. The encoding method according to claim 3, wherein the target bitstream comprises the first random seed and the second random seed.

9. The encoding method according to claim 8, wherein the target bitstream comprises an initial first random seed and an initial second random seed.

10. A decoding method, comprising:
obtaining a quantized signal from a received target bitstream, wherein the quantized signal comprises at least one of a first quantized signal or a second quantized signal, the first quantized signal is obtained by performing first quantization on a first multiple description signal, the second quantized signal is obtained by performing second quantization on a second multiple description signal, and the first multiple description signal and the second multiple description signal are obtained from a same signal; and
obtaining a decoded signal based on at least one of the first quantized signal or the second quantized signal.

11. The decoding method according to claim 10, wherein the target bitstream comprises indication information which indicates whether the target bitstream is a bitstream generated based on at least two multiple description signals, and
the obtaining the decoded signal based on at least one of the first quantized signal or the second quantized signal, comprises:
obtaining the decoded signal based on the indication information and at least one of the first quantized signal or the second quantized signal.

12. The decoding method according to claim 11, wherein the indication information indicates that the target bitstream is the bitstream generated based on the at least two multiple description signals, and the number of the obtained quantized signals is at least two.

13. The decoding method according to claim 12, wherein the obtaining the decoded signal based on the indication information and at least one of the first quantized signal or the second quantized signal, comprises:
obtaining a target signal according to a combination of the first quantized signal and the second quantized signal; and
obtaining the decoded signal based on the target signal.

14. The decoding method according to claim 13, wherein the obtaining the target signal according to the combination of the first quantized signal and the second quantized signal, comprises:
determining the target signal according to a mean or a weighted sum of the first quantized signal and the second quantized signal.

15. The decoding method according to claim 10, further comprising:
obtaining a random seed corresponding to the quantized signal from the target bitstream to obtain the target signal.

16. The decoding method according to claim 12, wherein the obtaining the decoded signal based on the indication information and at least one of the first quantized signal or the second quantized signal, comprises:
updating a first random seed corresponding to the first quantized signal to obtain an updated first random seed, and updating a second random seed corresponding to the second quantized signal to obtain an updated second random seed;
updating the first quantized signal based on the updated first random seed to obtain an updated first quantized signal, and updating the second quantized signal based on the updated second random seed to obtain an updated second quantized signal;
determining the target signal according to a mean or a weighted sum of the updated first quantized signal and the updated second quantized signal; and
obtaining the decoded signal based on the target signal.

17. The decoding method according to claim 16, wherein the first random seed corresponding to the first quantized signal comprises an initial first random seed, and the second random seed corresponding to the second quantized signal comprises an initial second random seed.

18. An electronic device, comprising:
one or more processing apparatus; and
a storage apparatus configured to store one or more programs, which
when executed by the one or more processing apparatus, cause the one or more processing apparatus to implement a decoding method according to claim 10 or an encoding method, comprising:
obtaining at least two multiple description signals according to a to-be-coded signal, the at least two multiple description signals comprising a first multiple description signal and a second multiple description signal;
performing first quantization on the first multiple description signal to obtain a first candidate quantized signal set, and performing second quantization on the second multiple description signal to obtain a second candidate quantized signal set;
obtaining a first quantized signal corresponding to the first multiple description signal and a second quantized signal corresponding to the second multiple description signal according to the first candidate quantized signal set and the second candidate quantized signal set; and
encoding the first quantized signal and the second quantized signal to generate a target bitstream corresponding to the to-be-coded signal.

19. A non-transitory storage medium comprising computer-executable instructions, which when executed by a computer processor, perform a decoding method claim 10 or an encoding method, comprising:
obtaining at least two multiple description signals according to a to-be-coded signal, the at least two multiple description signals comprising a first multiple description signal and a second multiple description signal;
performing first quantization on the first multiple description signal to obtain a first candidate quantized signal set, and performing second quantization on the second multiple description signal to obtain a second candidate quantized signal set;
obtaining a first quantized signal corresponding to the first multiple description signal and a second quantized signal corresponding to the second multiple description signal according to the first candidate quantized signal set and the second candidate quantized signal set; and
encoding the first quantized signal and the second quantized signal to generate a target bitstream corresponding to the to-be-coded signal.
